(19) United States
(12) Patent Application Publication
(10) Pub. No.: US 2025/0130510 A1
(43) Pub. Date: Apr. 24, 2025

(54) VIBRATION CONTROL OF STRUCTURAL ELEMENTS OF EXPOSURE APPARATUS

(71) Applicant: Nikon Corporation, Tokyo (JP)

(72) Inventors: Pai-Hsueh Yang, Palo Alto, CA (US); Hiroyoshi Asaumi, Kawasaki (JP); Koichi Sakata, Yokohama (JP); Kensuke Tokumi, Tokyo (JP); Shigeki Kitabatake, Kawasaki (JP); Christopher Sean Margeson, Mountain View, CA (US); Hwan Lee, Union City, CA (US); Bausan Yuan, San Jose, CA (US)

(73) Assignee: Nikon Corporation, Tokyo (JP)

(21) Appl. No.: 19/005,395

(22) Filed: Dec. 30, 2024

Related U.S. Application Data
(63) Continuation of application No. PCT/US2023/070966, filed on Jul. 25, 2023.
(60) Provisional application No. 63/393,161, filed on Jul. 28, 2022.

(51) Int. Cl. G03F 7/00

(52) U.S. Cl. CPC G03F 7/709; G03F 7/70508; G03F 7/70525; G03F 7/70716; G03F 7/70758; G03F 7/70766; G03F 7/7085

(57) ABSTRACT

A method of controlling vibration of a structural element of an exposure apparatus includes receiving data of a position of the structural element, determining a position error signal based at least in part on the position data and a specified position of the structural element, determining a force command to damp a specified vibration mode frequency of the structural element based at least in part on the position error signal and the specified vibration mode frequency, and transmitting the force command to an actuator such that the actuator applies force to the structural element and damps vibration of the structural element at least at the specified vibration mode frequency of the structural element.

### CROSS REFERENCE TO RELATED APPLICATIONS

This application is a continuation of International Application No. PCT/US2023/070966, filed Jul. 25, 2023, which claims the benefit of U.S. Provisional Application No. 63/393,161, filed Jul. 28, 2022. Each of the above applications is incorporated herein by reference in its entirety.

### FIELD

The present disclosure pertains to systems and methods of controlling and/or reducing vibration of structural elements in precision systems, such as lithography exposure apparatus.

### BACKGROUND

In a photolithographic process to manufacture microelectronic devices such as liquid crystal display devices or semiconductor devices (such as integrated circuits), an exposure apparatus is used which transfers a predetermined pattern on a photo mask or a reticle onto a substrate, such as a photosensitive glass plate or a wafer, by exposing the substrate to an illumination light (e.g., an energy beam) via a projection optical system (e.g., including a plurality of lenses). In such systems, the reticle and the substrate must be precisely aligned in order to expose the substrate and form the desired features, which can be a few nanometers in size. However, vibration of the support structure of the exposure apparatus and its various subsystems can result in motion of the reticle, the projection optical system, and/or the substrate relative to each other during exposures, which can negatively affect formation of the features on the substrate. Vibration of the support structures at relatively low frequencies can be particularly problematic. Passive mass dampers on such structures require tedious manual adjustment, and their effectiveness is often limited by space constraints within the machine. Accordingly, there exists a need for improvements to systems for controlling vibration of support structures in lithography exposure apparatus.

### SUMMARY

Certain embodiments of the disclosure pertain to systems and methods of controlling or reducing vibration of structural members or assemblies of precision systems, such as lithography exposure apparatus. In a representative embodiment, a method comprises receiving data of a position of a structural element of an exposure apparatus, determining a position error signal based at least in part on the position data and a specified position of the structural element, applying phase correction to the position error signal, determining a force command to damp a specified vibration mode frequency of the structural element based at least in part on the position error signal to which the phase correction has been applied and the specified vibration mode frequency, and transmitting the force command to an actuator such that the actuator applies force to the structural element and damps vibration of the structural element at least at the specified vibration mode frequency of the structural element.

In any or all of the disclosed embodiments, the method further includes obtaining the position data by integrating an acceleration signal received from a sensor.

In any or all of the disclosed embodiments, determining the force command further comprises filtering the position error signal with a low-pass filter.

In any or all of the disclosed embodiments, the low-pass filter includes derivative control.

In any or all of the disclosed embodiments, the phase correction is applied with the low-pass filter.

In any or all of the disclosed embodiments, determining the force command further comprises filtering the position error signal with a bandpass filter.

In any or all of the disclosed embodiments, determining the force command further comprises filtering the position error signal with a notch filter.

In any or all of the disclosed embodiments, data of the position of the structural element is received from a sensor coupled to the structural element at a location remote from the actuator.

In any or all of the disclosed embodiments, the specified vibration mode frequency is 2 Hz to 10 kHz, 2 Hz to 5 kHz, 2 Hz to 1 kHz, 2 Hz to 500 Hz, 2 Hz to 300 Hz, 2 Hz to 200 Hz, or 2 Hz to 100 Hz.

In any or all of the disclosed embodiments, the specified vibration frequency is lower than a vibration mode frequency of the actuator.

In any or all of the disclosed embodiments, determining the force command further comprises determining the force command to damp a plurality of specified vibration mode frequencies of the structural element.

In any or all of the disclosed embodiments, the structural element is an optical surface plate, a substrate stage, or a mask stage of the exposure apparatus.

In another representative embodiment, a system comprises an exposure apparatus including a structural element, an actuator system coupled to the structural element, the actuator system comprising an actuator and a sensor, and a control system configured to receive data of a position of the structural element from the sensor, determine a position error signal based at least in part on the position data and a specified position of the structural element, apply phase correction to the position error signal, determine a force command to damp a specified vibration mode frequency of the structural element based at least in part on the position error signal to which the phase correction has been applied and the specified vibration mode frequency, and transmit the force command to the actuator such that the actuator applies force to the structural element and damps vibration of the structural element at least at the specified vibration mode frequency of the structural element.

In any or all of the disclosed embodiments, the control system is further configured to obtain the position data by integrating an acceleration signal received from a sensor.

In any or all of the disclosed embodiments, the control system is further configured to filter the position error signal with a low-pass filter.

In any or all of the disclosed embodiments, the low-pass filter includes derivative control.

In any or all of the disclosed embodiments, the phase correction is applied by the low-pass filter.

any or all of the disclosed embodiments, the control system is further configured to filter the position error signal with a bandpass filter.

In any or all of the disclosed embodiments, the control system is further configured to filter the position error signal with a notch filter.

In any or all of the disclosed embodiments, the sensor is spaced apart from the actuator on the structural element.

In any or all of the disclosed embodiments, the specified vibration mode frequency is 2 Hz to 10 kHz, 2 Hz to 5 kHz, 2 Hz to 1 kHz, 2 Hz to 500 Hz, 2 Hz to 300 Hz, 2 Hz to 200 Hz, or 2 Hz to 100 Hz.

In any or all of the disclosed embodiments, the structural element is an optical surface plate, a substrate stage, or a mask stage of the exposure apparatus.

In another representative embodiment, a method comprises receiving data of a position of a structural element of an exposure apparatus, determining a position error signal based at least in part on the position data and a specified position of the structural element, filtering the position error signal with a low-pass filter including derivative control, applying phase correction to the position error signal with the low-pass filter, determining a force command to damp a specified vibration mode frequency of the structural element based at least in part on the filtered, phase-corrected position error signal, and transmitting the force command to an actuator coupled to the structural element such that the actuator applies force to the structural element and damps vibration of the structural element at least at the specified vibration mode frequency of the structural element.

The foregoing and other objects, features, and advantages of the disclosed technology will become more apparent from the following detailed description, which proceeds with reference to the accompanying figures.

### BRIEF DESCRIPTION OF THE DRAWINGS

FIG. 1 is a view schematically showing a structure of a liquid crystal exposure apparatus according to a first embodiment.

FIG. 2 is a view showing a substrate stage device that the liquid crystal exposure apparatus in FIG. 1 has.

FIG. 3 is a schematic view of a substrate measurement system that the liquid crystal exposure apparatus in FIG. 1 has.

FIG. 4 is a view (No. 1) used to explain an operation of a substrate stage device.

FIG. 5 is a view (No. 2) used to explain an operation of a substrate stage device.

FIG. 6 is a block diagram showing an input/output relation of a main controller that mainly structures a control system of the liquid crystal exposure apparatus.

FIG. 7 is a schematic side-elevation view of an actuator system coupled to a structural element, according to one embodiment.

FIG. 8 is a schematic diagram illustrating a structural element and an actuator system represented as a mass-spring-damper system.

FIGS. 9 and 10 are Bode plots illustrating the open loop frequency response of the mass-spring-damper system of FIG. 8 to various excitation forces.

FIG. 11 is a schematic block diagram of a control system for controlling vibration at a vibration mode frequency of a structural element, according to one embodiment.

FIG. 12 is a process flow diagram illustrating a representative method of controlling structural mode vibrations of a structural element, according to one embodiment.

FIG. 13 is a schematic block diagram of a control system for controlling vibration at multiple vibration mode frequencies of a structural element, according to one embodiment.

FIG. 14 is a top plan view of an actuator system coupled to a plate member, according to one embodiment.

FIG. 15 is a schematic block diagram of a control system for controlling vibration at two vibration mode frequencies of the plate member of FIG. 14, according to one embodiment.

FIGS. 16A-16C illustrate graphs of acceleration versus time and acceleration versus frequency when the plate member of FIG. 14 is acted on by an impulse force.

FIG. 17 is a Bode plot illustrating the magnitude and phase of the frequency response of the system without feedback control, with damping control of a first vibration mode, and with damping control of both first and second modes.

FIG. 18 is a side elevational view of another experimental system including a beam member supported by two support members and with an actuator system mounted on the beam member.

FIG. 19 schematically illustrates the first and second vibration modes of the beam member of FIG. 18.

FIG. 20 is a Bode plot illustrating the magnitude and phase of the open loop frequency response of the system 700 as measured by the two accelerometers of the actuator system.

FIG. 21 is a Bode plot showing the open loop frequency response of the system 700 and the frequency response applying control with position data derived from the accelerometer co-located with the actuator in FIG. 18.

FIGS. 22A-22B include plots of acceleration versus time and fast Fourier transforms (FFT) illustrating the open loop impulse response of the system (FIG. 22A) and the impulse response of the system applying control with position data derived from the first accelerometer in FIG. 18 (FIG. 22B).

FIG. 23 is a Bode plot showing the open loop frequency response of the system of FIG. 18 and the frequency response applying control with position data derived from the second accelerometer.

FIGS. 24A and 24B include plots of acceleration versus time and fast Fourier transforms illustrating the open loop impulse response of the system of FIG. 18 (FIG. 24A) and the impulse response of the system of FIG. 18 applying control with position data derived from the second accelerometer (FIG. 24B).

FIG. 25 is a side elevation view of another embodiment of an experimental structural system.

FIGS. 26-28 are Bode plots illustrating three structural vibration modes of the system of FIG. 25.

FIG. 29 is a schematic block diagram illustrating a control system configured to implement a peak filter control channel in parallel with a damping filter control channel, according to another embodiment.

FIGS. 30 and 31 are Bode plots of the dynamic response of the system of FIG. 25 when controlled by the control system of FIG. 29.

FIG. 32 includes graphs of acceleration versus time and acceleration versus frequency of the system of FIG. 25 when controlled by the system of FIG. 29.

FIG. 33 is a top plan view of another embodiment of a structural system including a rectangular plate member and an actuator and a plurality of accelerometer sensors coupled to the plate member.

FIG. 34 illustrates another embodiment of a control system including two control loops configured to control vibrations of the four modes of the structure of FIG. 33.

FIG. 35 is a Bode plot of the open loop frequency response of the system of FIG. 33 when excited by an impulse.

FIG. 36 is a Bode plot of the frequency response of the system applying control of four vibration modes based on force commands from the control system of FIG. 34.

FIGS. 37A-37B include plots of acceleration versus time and acceleration versus frequency for the system of FIG. 33.

FIG. 38 is a top plan view of another configuration of four accelerometers, an actuator, and a shaker on a plate member.

FIG. 39 illustrates another embodiment of a control system including two control loops configured to control vibrations of the four modes of the structure of FIG. 38.

FIG. 40 illustrates surface deformations of a rectangular plate at nine vibration modes of the plate based on a finite element analysis model of the plate.

FIGS. 41-44 schematically illustrate input and output coordinates of a modal space model of a structural element in various vibration modes.

FIG. 45 is a schematic diagram of an immersion microlithography system, which is another example of a precision system including a stage assembly as described herein.

FIG. 46 is a schematic diagram of an extreme-UV microlithography system, which is another example of a precision system including a stage assembly as described herein.

FIG. 47 is a process-flow diagram depicting exemplary steps associated with a process for fabricating semiconductor devices.

FIG. 48 is a process-flow diagram depicting exemplary steps associated with processing a substrate (e.g., a wafer), as would be performed, for example, in the process shown in FIG. 47.

FIG. 49 is a schematic depiction of a microlithography system, as an exemplary precision system, comprising a stage assembly as disclosed herein that includes at least one holding device.

FIG. 50 is a schematic block diagram illustrating a representative computer control system for implementing the disclosed systems and methods.

### DETAILED DESCRIPTION

Certain embodiments of the present disclosure pertain to actuator systems and associated control systems and methods that can be used to control/reduce/attenuate vibration of structural elements in a precision system, such as a lithography exposure apparatus. In certain embodiments, the actuator and control systems described herein can be tuned to attenuate relatively low-frequency vibrations, such as resonant modes of a structure excited by reaction forces applied by moving components of the system, such as substrate stages, mask stages, etc., although the control systems can be configured to detect and attenuate structural mode vibrations having a frequency anywhere within the sampling rate frequency range of the system and/or the amplifier bandwidth of the actuator, such as of 2 Hz to 10 KHz.

In certain embodiments, the actuator systems can comprise an actuator such as a voice coil motor, and one or a plurality of motion sensors such as accelerometers, although other types of actuators and/or sensors can be used. The actuator(s) and sensor(s) can be positioned on a structural element at the same location or at different locations. In certain embodiments, the location of the actuator and the sensors can be selected such that the sensor(s) detect relatively large displacements of the structural element associated with a specified vibration mode or modes, and/or such that force applied to the structural element by the actuator results in relatively large displacement of the structural element and thus increased damping effect.

In certain embodiments, the control systems described herein can be configured to compensate for phase lag in the system associated with one or more of sensor position (e.g., as it relates to vibration mode shapes of the structural element), sensor bandwidth, and/or time delay associated with signal processing and digital control. In certain embodiments, the control systems can implement a combination of a low-pass filter, a bandpass filter, and/or one or a plurality of notch filters. In certain embodiments, one or more of the filters, such as the low-pass filter, can include derivative control. In certain embodiments, one or more of the filters, such as the low-pass filter, can be configured to apply phase correction to a position error signal received in the feedback control loop to compensate for the phase lag described above. In certain embodiments, the control systems can include a plurality of control elements implemented in parallel, wherein each control element comprises a combination of the filters described herein and is configured to generate a force command to attenuate vibration at a specified vibration mode frequency of the structural element while reducing coupling between modes. Thus, the control systems described herein can be configured to attenuate vibration at one or a plurality of vibration modes of a structural element, such as two modes, three modes, four modes, etc. In certain embodiments, the control systems can also be configured such that the actuator system can damp mode frequencies of the structural element that are lower than the mode frequency of the actuator-structure interaction, such as with a peak filter.

Implementing the control methodologies described herein, the actuator systems and control systems of the present disclosure can significantly reduce the magnitude of vibrations of a structural element excited due to reaction forces from relative motion of other structures in a precision system. The actuator systems and control systems can also significantly reduce the settling time of such structural elements, which can lead to significant improvements in substrate positioning accuracy and throughput of, for example, lithography exposure apparatuses.

### Example 1: Lithography Exposure Apparatus

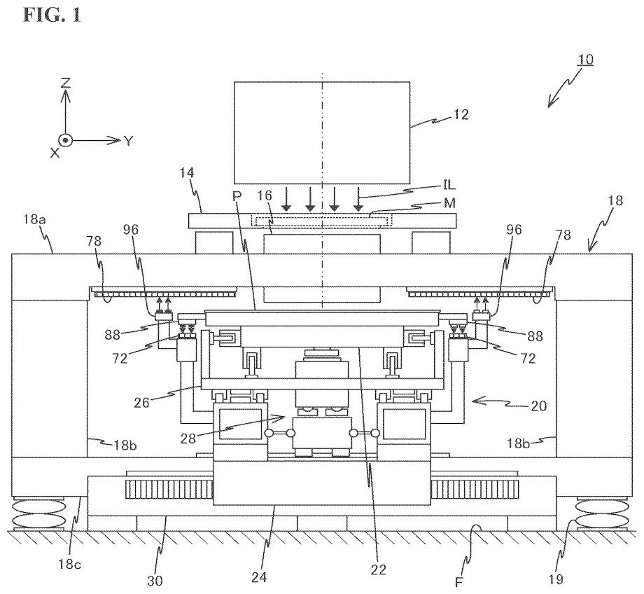

A representative embodiment of a first embodiment will be described, using FIGS. 1 to 6.

FIG. 1 schematically shows a structure of an exposure apparatus (here, a liquid crystal exposure apparatus 10) according to one embodiment. Liquid crystal exposure apparatus 10 is a projection exposure apparatus of a step-and-scan method, or a so-called scanner, whose exposure target is an object (here, a glass substrate P). Glass substrate P (hereinafter, simply referred to as “substrate P”) is formed in a rectangular shape (e.g., a square shape) in a planar view, and can be used in liquid crystal display devices (flat-panel displays) and the like.

Liquid crystal exposure apparatus 10 has an illumination system 12, a mask stage device 14 that holds a mask M on which a circuit pattern and the like is formed, a projection optical system 16, an apparatus main section 18, a substrate stage device 20 that holds substrate P whose surface (a surface facing a +Z direction in FIG. 1) is coated with a resist (e.g., a sensitive agent), a control system for these parts and the like. Hereinafter, a direction in which mask M and substrate P are each relatively scanned with respect to projection optical system 16 at the time of exposure will be described as an X-axis direction, a direction orthogonal to the X-axis direction in a horizontal plane will be described as a Y-axis direction, a direction orthogonal to the X-axis and the Y-axis will be described as a Z-axis direction (a direction parallel to an optical axis direction of projection optical system 16), and rotation directions around the X-axis, the Y-axis, and the Z-axis will each be described as a θx direction, a θy direction, and a θz direction. Also, position in the X-axis, the Y-axis, and the Z-axis directions will each be described as an X position, a Y position, and a Z position.

In certain embodiments, the illumination system 12 can be structured similarly to the illumination system disclosed in U.S. Pat. No. 5,729,331 and the like, and can irradiate mask M with a light emitted from a light source (such as a mercury lamp, or a laser diode) serving as an exposure illumination light (illumination light) IL, via a reflection mirror, a dichroic mirror, a shutter, a wavelength selection filter, various kinds of lenses and the like. As illumination light IL, light such as an i-line (wavelength 365 nm), a g-line (wavelength 436 nm), or an h-line (wavelength 405 nm) (or, a synthetic light of the i-line, the g-line, and the h-line described above) can be used.

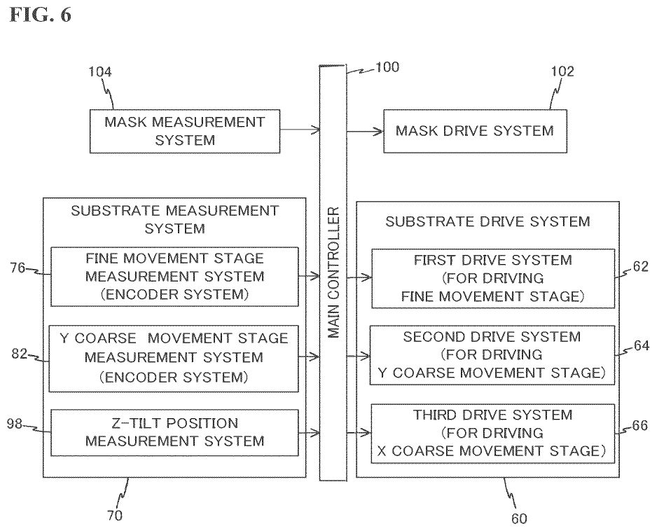

As mask M that mask stage device 14 holds, a transmission type photomask is used. On the lower surface (a surface facing the −Z direction in FIG. 1) of mask M, a predetermined circuit pattern is formed. Mask M is moved in predetermined long strokes in a scanning direction (the X-axis direction) and also is finely moved appropriately in the Y-axis direction and the θz direction by a main controller 100, via a mask drive system 102 including a linear motor, an actuator such as a ball screw device and the like (refer to FIG. 6). Position information (including rotation amount information in the Oz direction; the same applies hereinafter) of mask M within an XY plane can be obtained by main controller 100 via a mask measurement system 104 including an encoder system or a measurement system such as an interferometer system.

Projection optical system 16 is arranged below the mask stage device 14. Projection optical system 16 is a so-called multi-lens projection optical system, and can have a structure similar to the projection optical system disclosed in U.S. Pat. No. 6,552,775 and the like, and is equipped with a plurality of lens modules that form an upright normal image with a double telecentric equal magnifying system.

In liquid crystal exposure apparatus 10, when illumination light IL illuminates an illumination area on mask M, illumination light IL passes through (is transmitted) mask M to form a projection image (partial upright image) of the circuit pattern of mask M within the illumination area on an irradiation area (exposure area) on substrate P conjugate with the illumination area, via projection optical system 16. Then by mask M relatively moving in the scanning direction with respect to illumination area (illumination light IL) along with substrate P relatively moving in the scanning direction with respect to the exposure area (illumination light IL), scanning exposure of one shot area on substrate P is performed, and the pattern formed on mask M is transferred on the shot area.

Apparatus main section 18 supports mask stage device 14 and projection optical system 16, and is installed on a floor F in a clean room via a vibration isolation device 19. Apparatus main section 18 can be structured similarly to the apparatus main section disclosed in U.S. Patent Application Publication No. 2008/0030702, and has an upper mount section 18a, a pair of middle mount section 18b, and a lower mount section 18c. Since upper mount section 18a is a member that supports projection optical system 16, hereinafter, in the embodiment, upper mount section 18a will be referred to and described as “optical surface plate 18a.” Here, in the scanning exposure operation using liquid crystal exposure apparatus 10 in the embodiment, since position control of substrate P is performed with respect to illumination light IL irradiated via projection optical system 16, optical surface plate 18a that supports projection optical system 16 functions as a reference member when performing position control of substrate P.

Substrate stage device 20 is a device used to perform position control of substrate P with high precision with respect to projection optical system 16 (illumination light IL), that moves substrate P along a horizontal plane (the X-axis direction and the Y-axis direction) in predetermined long strokes and also finely moves substrate P in directions of six degrees of freedom. While the structure of the substrate stage device used in liquid crystal exposure apparatus 10 is not limited in particular, in the illustrated embodiment, as an example, a substrate stage device 20 of a so-called coarse/fine movement structure is used that includes a gantry type two-dimensional coarse movement stage and a fine movement stage which is finely moved with respect to the two-dimensional coarse movement stage, as is disclosed in U.S. Patent Application Publication No. 2012/0057140 and the like.

Substrate stage device 20 is equipped with a fine movement stage 22, a Y coarse movement stage 24, an X coarse movement stage 26, a support section (a weight canceling device 28 here), a pair of base frames 30 (one of the pair is not shown in FIG. 1, refer to FIG. 4), a substrate drive system 60 (refer to FIG. 6) used to move each component of substrate stage device 20, a substrate measurement system 70 (refer to FIG. 6) used to measure position information on each component described above, and the like.

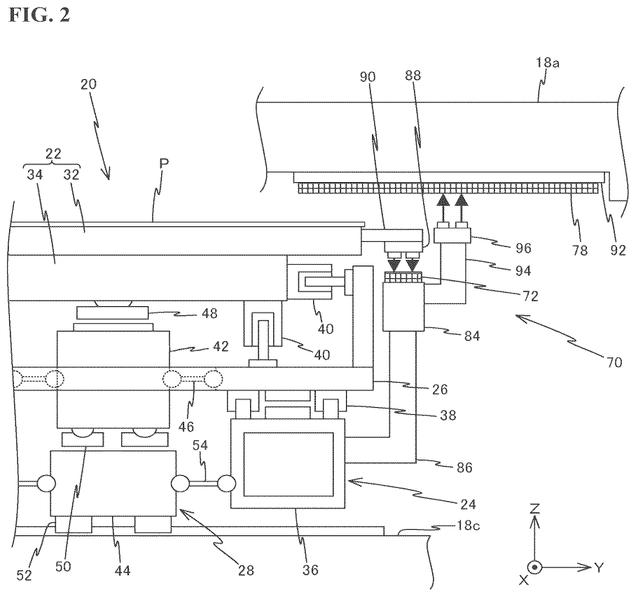

As is shown in FIG. 2, fine movement stage 22 is equipped with a substrate holder 32 and a stage main section 34. Substrate holder 32 is formed in a plate shape (or in a box shape) having a rectangular shape in a planar view (refer to FIG. 4), substrate P is mounted on its upper surface (substrate mount surface). The size of the upper surface of substrate holder 32 in the X-axis and Y-axis directions is set to around the same size as (actually slightly shorter than) substrate P. Substrate P, by being held by vacuum suction by substrate holder 32 in a state mounted on the upper surface of substrate holder 32, has its flatness corrected almost entirely (the entire surface) along the upper surface of substrate holder 32. Stage main section 34 comprises a plate shape (or a box shape) member having a rectangular shape in a planar view whose size in the X-axis and Y-axis directions is shorter than substrate holder 32, and is connected integrally to the lower surface of substrate holder 32.

Referring back to FIG. 1, Y coarse movement stage 24 is below (on the −Z side of) fine movement stage 22, and is arranged on the pair of base frames 30. Y coarse movement stage 24, as is shown in FIG. 4, has a pair of X beams 36. The pair of X beams 36 is arranged parallel to the Y-axis direction at a predetermined spacing. The pair of X beams 36 is mounted on the pair of base frames 30 via a mechanical linear guide device, and is freely movable in the Y-axis direction on the pair of base frames 30.

Referring back to FIG. 1, X coarse movement stage 26 is above (on the +Z side of) Y coarse movement stage 24, and is arranged below fine movement stage 22 (in between fine movement stage 22 and Y coarse movement stage 24). X coarse movement stage 26 is a plate shape member having a rectangular shape in a planar view, the stage being mounted on the pair of X beams 36 (refer to FIG. 4) that Y coarse movement stage 24 has via a plurality of mechanical linear guide devices 38 (refer to FIG. 2), and the stage is freely movable in the X-axis direction with respect to Y coarse movement stage 24, while being moved integrally with Y coarse movement stage 24 in the Y-axis direction.

As is shown in FIG. 6, substrate drive system 60 is equipped with: a first drive system 62 for finely moving fine movement stage 22 in directions of six degrees of freedom (in each of the X-axis, the Y-axis, the Z-axis, the θx, the θy, and the θz directions) with respect to optical surface plate 18a, a second drive system 64 for moving Y coarse movement stage 24 in long strokes in the Y-axis direction on base frames 30 (each refer to FIG. 1), and a third drive system 66 for moving X coarse movement stage 26 in long strokes in the X-axis direction on Y coarse movement stage 24 (each refer to FIG. 1). While the type of actuators that structure the second drive system 64 and the third drive system 66 is not limited in particular, as an example, a linear motor, a ball screw driver or the like can be used (FIG. 1 and the like show a linear motor).

While the type of actuators that structure the first drive system 62 is also not limited in particular, in FIG. 2 and the like, as an example, a plurality of linear motors (voice coil motors) 40 is shown (X linear motors are not shown in FIGS. 1 and 2) that generates thrust in each of the X-axis, the Y-axis, and the Z-axis directions. Each linear motor 40 has a stator attached to X coarse movement stage 26, and also a mover attached to stage main section 34 of fine movement stage 22, and to fine movement stage 22, thrust is given in directions of six degrees of freedom via each linear motor 40 with respect to X coarse movement stage 26. A detailed structure of each of the first to third drive systems 62, 64, and 66, as an example, is disclosed in, U.S. Patent Application Publication No. 2010/0018950.

Main controller 100 gives thrust to fine movement stage 22 using the first drive system 62 so that relative position between fine movement stage 22 and X coarse movement stage 26 (each refer to FIG. 1) stays within a predetermined range in the X-axis and the Y-axis directions. Here, “position stays within a predetermined range,” on moving fine movement stage 22 with long strokes in the X-axis or the Y-axis direction, is used merely to imply that X coarse movement stage 26 (in the case fine movement stage 22 is moved in the Y-axis direction, X coarse movement stage 26 and Y coarse movement stage 24) and fine movement stage 22 are moved almost at the same speed in the same direction, and that fine movement stage 22 and X coarse movement stage 26 do not necessarily have to move in strict synchronization and a predetermined relative movement (relative position displacement) is permissible.

Referring back to FIG. 2, weight canceling device 28 is equipped with a weight canceling device 42 that supports the weight of fine movement stage 22 from below, and a Y step guide 44 that supports weight canceling device 42 from below.

Weight canceling device 42 (also referred to as a central pillar) is inserted into an opening section formed in X coarse movement stage 26, and is mechanically connected at the height of the center-of-gravity position to X coarse movement stage 26, via a plurality of connecting members 46 (also referred to as a flexure device). X coarse movement stage 26 and weight canceling device 42 are connected by the plurality of connecting members 46, in a state of vibratory (physical) separation in the Z-axis direction, the Ox direction, and the Oy direction. Weight canceling device 42, by being pulled by X coarse movement stage 26, moves integrally with X coarse movement stage 26, in the X-axis and/or the Y-axis direction.

Weight canceling device 42 supports the weight of fine movement stage 22 from below in a non-contact manner via a pseudospherical bearing device called a leveling device 48. This allows relative movement of fine movement stage 22 in the X-axis, the Y-axis, and Oz direction with respect to weight canceling device 42 and oscillation (relative movement in the Ox and Oy directions) with respect to the horizontal plane. As for the structure and function of weight canceling device 42 and leveling device 48, an example is disclosed in U.S. Patent Application Publication No. 2010/0018950.

Y step guide 44 comprises a member extending parallel to the X-axis, and is arranged in between the pair of X beams 36 that Y coarse movement stage 24 has (refer to FIG. 4). The upper surface of Y step guide 44 is set parallel to the XY plane (horizontal plane), and weight canceling device 42 is mounted on Y step guide 44 in a non-contact manner, via an air bearing 50. Y step guide 44 functions as a surface plate when weight canceling device 42 (that is, fine movement stage 22 and substrate P) moves in the X-axis direction (scanning direction). Y step guide 44 is mounted on lower mount section 18 c via a mechanical linear guide device 52, and while being freely movable in the Y-axis direction with respect to lower mount section 18c, relative movement in the X-axis direction is restricted.

Y step guide 44 is mechanically connected (refer to FIG. 4) at the height of the center-of-gravity position to Y coarse movement stage 24 (the pair of X beams 36), via a plurality of connecting members 54. Connecting members 54 are flexure devices similarly to connecting members 46 described above that connect Y coarse movement stage 24 and Y step guide 44 in a state of vibratory (physical) directions of five degrees of freedom; excluding the Y-axis direction in directions of six degrees of freedom. Y step guide 44, by being pulled by Y coarse movement stage 24, moves integrally with Y coarse movement stage.

The pair of base frames 30, as is shown in FIG. 4, each consists of a member extending parallel to the Y-axis, and is installed parallel to each other on floor F (refer to FIG. 1). Base frames 30 are physically (or vibrationally) separate from apparatus main section 18.

Next, substrate measurement system 70 for obtaining position information on substrate P (actually, fine movement stage 22 holding substrate P) in directions of six degrees of freedom will be described.

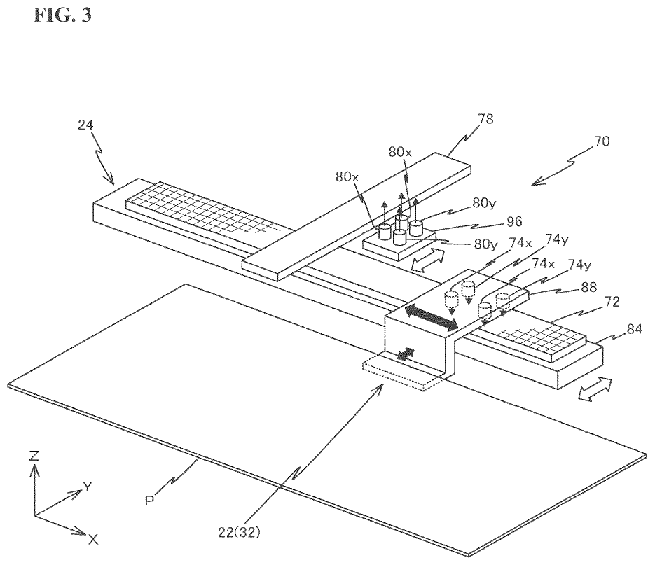

FIG. 3 shows a schematic view of substrate measurement system 70. Substrate measurement system 70 is equipped with: a first measurement system (here, a fine movement stage measurement system 76 (refer to FIG. 6)) including a first scale (here, an upward scale 72) that Y coarse movement stage 24 has (associated with Y coarse movement stage 24) and a first head (here, downward X heads 74x and downward Y heads 74y) that fine movement stage 22 has, and a second measurement system (here, a coarse movement stage measurement system 82 (refer to FIG. 6)) including a second scale (here, a downward scale 78) that optical surface plate 18a (refer to FIG. 2) has and a second head (here, upward X heads 80 x and upward Y heads 80 y) that Y coarse movement stage 24 has. Note that in FIG. 3, fine movement stage 22 is shown, modeled as a member holding substrate P. Also, spacing (pitch) between gratings in a diffraction grating that each of the scales 72 and 78 has is illustrated greatly wider than the actual spacing. The same applies to other drawings as well. Also, since the distance between each head and each scale is greatly shorter than the distance between a laser light source and a bar mirror of a conventional optical interferometer system, influence of air fluctuation is less than that of the optical interferometer system, which allows position control of substrate P with high precision so that the exposure accuracy can be improved.

Upward scale 72 is fixed to the upper surface of a scale base 84. Scale base 84 is arranged as is shown in FIG. 4, one on the +Y side and one on the −Y side of fine movement stage 22. Scale base 84, as is shown in FIG. 2, is fixed to X beams 36 of Y coarse movement stage 24, via an arm member 86 formed in an L-shape when viewed from the X-axis direction. Accordingly, scale base 84 (and upward scale 72) can be moved in predetermined long strokes in the Y-axis direction integrally with Y coarse movement stage 24. As for arm member 86, as is shown in FIG. 4, while two are arranged separately in the X-axis direction for one X beam 36, the number of arm member 86 is not limited to this, and can be appropriately increased or decreased.

Scale base 84 is a member extending parallel to the X-axis, and the length in the X-axis direction is set to around twice the length (about the same as Y step guide 44) in the X-axis direction of substrate holder 32 (that is, substrate P (not shown in FIG. 4)). Scale base 84 is preferably formed with a material such as ceramics and the like that hardly generates thermal deformation. The same applies to other members to be described later on; scale base 92, and head bases 88 and 96.

Upward scale 72 is a plate shaped (strip shaped) member extending in the X-axis direction, and on its upper surface (a surface facing the +Z side (upper side)), a reflection type two-dimensional grating (so-called grating) is formed whose periodic direction is in two-axis directions (in the embodiment, X-axis and Y-axis directions) orthogonal to each other.

To each of the center section of the side surface on the +Y side and −Y side of substrate holder 32, head base 88 is fixed (refer to FIG. 2) via an arm member 90 corresponding to scale base 84 described above. Each of the downward heads 74 x and 74 y (refer to FIG. 3) is fixed to the lower surface of head base 88.

In fine movement stage measurement system 76 (refer to FIG. 6) of the embodiment, as is shown in FIG. 3, to one head base 88, two downward X heads 74x are arranged separately in the X-axis direction, and two downward Y heads 74y are arranged separately in the X-axis direction. Each of the heads 74x and 74y irradiates the corresponding upward scale 72 with a measurement beam, and also receives light (here, a diffracted light) from upward scale 72. Light from upward scale 72 is supplied to a detector, and the output of the detector is supplied to main controller 100 (refer to FIG. 6). Main controller 100 obtains relative movement amount of each of the heads 74x and 74y with respect to scale 72, based on the output of the detector. Note that in the description, “head” simply means a section that emits a measurement beam onto a diffraction grating as well as a section where light from the diffraction grating is incident on, and the head itself illustrated in each of the drawings does not have to have a light source and a detector.

As is described so far, in fine movement stage measurement system 76 of the embodiment (refer to FIG. 6), with the total of four (two each on the +Y side and the −Y side of substrate P) downward X heads 74x and the corresponding upward scale 72, four X linear encoder systems are structured, and with the total of four (two each on the +Y side and the −Y side of substrate P) downward Y heads 74y and the corresponding upward scale 72, four Y linear encoder systems are structured. Main controller 100 (refer to FIG. 6), by using the output of the four X linear encoder systems and the four Y linear encoder systems described above, obtains position information (hereinafter called “first information”) on fine movement stage 22 (substrate P) in the X-axis direction, the Y-axis direction, and the Oz direction.

Here, with upward scale 72, measurable distance in the X-axis direction is set longer than the measurable distance in the Y-axis direction. Specifically, as is shown in FIG. 4, the length in the X-axis direction of upward scale 72 is around the same length as scale base 84, and is set around to a length that can cover a movable range in the X-axis direction of fine movement stage 22. Meanwhile, the width direction (Y-axis direction) size (and spacing between a pair of heads 74x and 74y adjacent in the Y-axis direction) of upward scale 72 is set to about a length so that the measurement beam from each of the heads 74x and 74y does not move off from the grating surface (surface to be measured) of the corresponding upward scale 72, even when fine movement stage 22 is finely moved in the Y-axis direction with respect to upward scale 72.

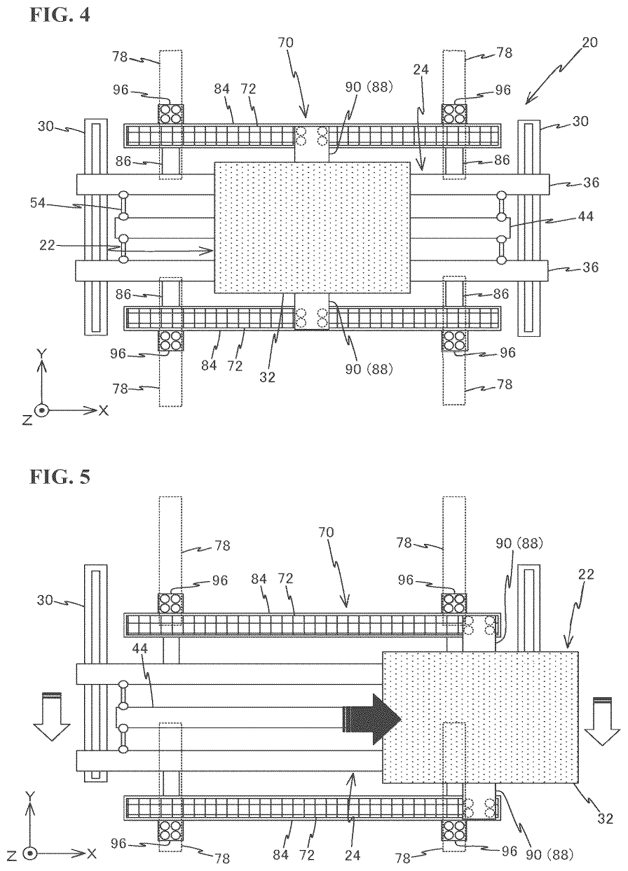

Next, an operation of fine movement stage measurement system 76 (refer to FIG. 6) will be described, using FIGS. 4 and 5. FIGS. 4 and 5 show substrate stage device 20 before and after fine movement stage 22 moves in long strokes in the X-axis and the Y-axis directions. FIG. 4 shows fine movement stage 22 in a state positioned almost at the center of the movable range in the X-axis and the Y-axis directions, and FIG. 5 shows fine movement stage 22 in a state positioned at the +X side stroke end of the movable range in the X-axis direction and also at the −Y side stroke end in the Y-axis direction.

As can be seen from FIGS. 4 and 5, regardless of the position in the Y-axis direction of fine movement stage 22, the measurement beam from each of the heads 74x and 74y attached to fine movement stage 22 does not move off from the grating surface of upward scale 72 including the case when fine movement stage 22 is finely moved in the Y-axis direction. Also, when fine movement stage 22 moves in long strokes in the X-axis direction as well, the measurement beam from each of the downward heads 74x and 74y does not move off from the grating surface of upward scale 72.

Next, coarse movement stage measurement system 82 (refer to FIG. 6) will be described. Coarse movement stage measurement system 82 of the embodiment, as it can be seen from FIGS. 1 and 4, has two downward scales 78 (that is, a total of four downward scales 78) arranged separately in the X-axis direction on the +Y side and the −Y side of projection optical system 16 (refer to FIG. 1). Downward scale 78 is fixed to the lower surface of optical surface plate 18a, via scale base 92 (refer to FIG. 2). Scale base 92 is a plate shaped member extending in the Y-axis direction, and the length in the Y-axis direction is set to around the same (actually slightly longer) as the movable distance of fine movement stage 22 (that is, substrate P (not shown in FIG. 4)) in the Y-axis direction.

Downward scale 78 is a plate shaped (strip shaped) member extending in the Y-axis direction, and on its lower surface (a surface facing the −Z side (lower side)), a reflection type two-dimensional grating (so-called grating) is formed whose periodic direction is in two-axis directions (in the embodiment, X-axis and Y-axis directions) orthogonal to each other, similarly to the upward scale 72 described above. Note that the grating pitch of the diffraction grating that downward scale 78 has may be the same as, or different from the grating pitch of the diffraction grating that upward scale 72 has.

To each of the pair of scale bases 84 that Y coarse movement stage 24 has, as is shown in FIG. 2, head base 96 is fixed via an arm member 94 formed in an L shape when viewed from the X-axis direction. Head bases 96, as is shown in FIG. 4, are arranged near the ends on the +X side and on the −X side of scale base 84. Each of the upward heads 80x and 80y, as is shown in FIG. 3, is fixed to the upper surface of head base 96. Accordingly, a total of four head bases 96 (and upward heads 80x and 80y) can be moved in the Y-axis direction integrally with Y coarse movement stage 24.

With coarse movement stage measurement system 82 (refer to FIG. 6) of the embodiment, as is shown in FIG. 3, two upward X heads 80x and two upward Y heads 80y are arranged separately in the Y-axis direction for one head base 96. Each of the heads 80x and 80y irradiates the corresponding downward scale 78 with a measurement beam, and also receives light (here, a diffracted light) from downward scale 78. Light from downward scale 78 is supplied to a detector not shown, and the output of the detector is supplied to main controller 100 (refer to FIG. 6). Main controller 100 obtains relative movement amount of each of the heads 80x and 80y with respect to scale 78, based on the output of the detector. As is described so far, in coarse movement stage measurement system 82 of the embodiment, with a total of eight upward X heads 80 x and the corresponding downward scale 78, eight X linear encoder systems are structured, and also with a total of eight upward Y heads 80y and the corresponding downward scale 78, eight Y linear encoder systems are structured. Main controller 100 (refer to FIG. 6), by appropriately using the output of the eight X linear encoder systems and the eight Y linear encoder systems described above, obtains position information (hereinafter called “second information”) on Y coarse movement stage 24 in the X-axis direction, the Y-axis direction, and the θz direction.

Also, upward scale 72 fixed on scale base 84 and each of the upward heads 80x and 80y integrally fixed to scale base 84 via head base 96 are arranged, so that their mutual positional relation is to be invariant and that the positional relation is to be known. Hereinafter, information related to relative positional relation between upward scale 72 and each of the upward heads 80x and 80y integrally fixed thereto will be called “third information.” Note that while in the description, upward scale 72 and upward heads 80x and 80y were described to be arranged so that their the positional relation was to be invariant, liquid crystal exposure apparatus 10 may be equipped with a measurement system for measuring the positional relation between the two. The same applies to each embodiment that will be described below.

Main controller 100 (refer to FIG. 6) obtains position information on fine movement stage 22 (substrate P) within the XY plane with optical surface plate 18a (projection optical system 16) serving as a reference, based on the first to third information described above, and performs position control of substrate P with respect to projection optical system 16 (illumination light IL), using substrate drive system 60 (refer to FIG. 6) described above.

As is described, in substrate measurement system 70 of the embodiment, position information on Y coarse movement stage 24 which moves in long strokes in the Y-axis direction is obtained by coarse movement stage measurement system 82 including downward scale 78 whose measurable distance is longer in the Y-axis direction than that of the X-axis direction (the Y-axis direction serving as the main measurement direction), and position information on fine movement stage 22 which moves in long strokes in the X-axis direction is also obtained by fine movement stage measurement system 76 including upward scale 72 whose measurable distance is longer in the X-axis direction than that of the Y-axis direction (the X-axis direction serving as the main measurement direction). That is, in coarse movement stage measurement system 82 and fine movement stage measurement system 76, the moving direction of each encoder head (74x, 74y, 80x, and 80y) coincides with the main measurement direction of the corresponding scales (72 and 78).

Also, position information on fine movement stage 22 (substrate P) in each of the Z-axis, the θx, and the θy directions (hereinafter called “Z-tilt direction”) obtained by main controller 100 using a Z-tilt position measurement system 98 (each refer to FIG. 6). While the structure of Z-tilt position measurement system 98 is not limited in particular, as an example, it is possible to use a measurement system using a displacement sensor attached to fine movement stage 22, as is disclosed in U.S. Patent Application Publication No. 2010/0018950 and the like.

Note that although it is not shown, substrate measurement system 70 also has a measurement system for obtaining position information on X coarse movement stage 26. In the embodiment, since position information on fine movement stage 22 (substrate P) in the X-axis direction is obtained via Y coarse movement stage 24 with optical surface plate 18a serving as a reference, measurement accuracy of the X coarse movement stage 26 itself does not have to be the same level as fine movement stage 22. Position measurement of X coarse movement stage 26 may be performed, based on the output of fine movement stage measurement system 76 described above and the output of the measurement system (not shown) which measures the relative position between X coarse movement stage 26 and fine movement stage 22, or may be performed using an independent measurement system.

In liquid crystal exposure apparatus 10 (refer to FIG. 1) structured in the manner described above, loading of mask M onto mask stage device 14 is performed by a mask loader (not shown), along with loading of substrate P onto substrate holder 32 by a substrate loader (not shown), under the control of main controller 100 (refer to FIG. 6). Then, alignment measurement is executed using an alignment detection system (not shown) by main controller 100, and after the alignment measurement has been completed, exposure operation of a step-and-scan method is sequentially performed on a plurality of shot areas set on substrate P. In the alignment measurement operation and the exposure operation of the step-and-scan method, position information on fine movement stage 22 is measured by substrate measurement system 70.

With liquid crystal exposure apparatus 10 of the embodiment described so far, since the position of fine movement stage 22 (substrate P) is measured using substrate measurement system 70 which includes an encoder system, influence of air fluctuation is less than that of the conventional measurement using an optical interferometer system, which allows position control of substrate P with high precision so that the exposure accuracy can be improved.

Also, since substrate measurement system 70 performs position measurement of substrate P with downward scale 78 fixed to optical surface plate 18 a (apparatus main section 18) as a reference (via upward scale 72), position measurement of substrate P can be performed with projection optical system 16 substantially serving as a reference. This allows position control of substrate P to be performed with illumination light IL serving as a reference, which can improve exposure accuracy.

Note that the structure of substrate measurement system 70 described so far can be appropriately changed, as long as position information on fine movement stage 22 can be obtained at a desired accuracy in the movable range of fine movement stage 22 (substrate P).

That is, while a long scale having a length about the same as that of scale base 84 was used as upward scale 72 in the embodiment above, the scale is not limited to this, and scales having a shorter length in the X-axis direction may be arranged at a predetermined spacing in the X-axis direction, similarly to the encoder system disclosed in International Publication WO 2015/147319. In this case, since a gap is formed in between a pair of scales adjacent in the X-axis direction, by making the spacing in the X-axis direction of each of the pair of heads 74x and 74y adjacent in the X-axis direction wider than the gap described above, one of the heads 74x and one of the heads 74y should be made to constantly face the scale. The same applies for the relation between downward scale 78 and upward heads 80x and 80y.

Also, while upward scale 72 was arranged on the +Y side and the −Y side of fine movement stage 22, the arrangement is not limited to this, and the scale may be arranged only on one side (the +Y side, or the −Y side). In the case only one upward scale 72 is arranged, and a plurality of scales are arranged at a predetermined spacing (gap between scales) in the X-axis direction as is described above, the number and arrangement of each of the heads 74x and 74y should be set so that at least two downward X heads 74x (or downward Y heads 74y) constantly face the scale to allow position measurement of fine movement stage 22 in the θz direction to be performed at all times. The same applies for downward scale 78, and as long as position measurement of Y coarse movement stage 24 in the X-axis, the Y-axis, and the θz direction can be performed at all times, the number and arrangement of downward scale 78 and upward heads 80x and 80y can be appropriately changed.

Also, while a two-dimensional diffraction grating whose periodic direction is in the X-axis and the Y-axis directions were formed on upward scale 72 and downward scale 78, an X diffraction grating whose periodic direction is in the X-axis direction and a Y diffraction grating whose periodic direction is in the Y-axis direction may be formed separately on scales 72 and 78. Also, while the two-dimensional diffraction grating in the embodiment had periodic directions in the X-axis and the Y-axis directions, if position measurement of substrate P within the XY plane can be performed at a desired accuracy, the periodic direction of the diffraction grating is not limited to this, and can be appropriately changed.

Also, Z-tilt position information on substrate P may be measured by attaching a displacement sensor facing downward to head base 88, and also using the sensor with scale base 84 (or a reflection surface of upward scale 72) serving as a reference. Also, at least three heads of the plurality of downward heads 74 x and 74 y may serve as two-dimensional heads (so-called XZ heads or YZ heads) that can perform measurement in a vertical direction along with position measurement in a direction parallel to the horizontal plane, and Z-tilt position information on substrate P may be obtained by the two-dimensional heads using the grating surface of upward scale 72. Similarly, Z-tilt position information on Y coarse movement stage 24 may be measured with scale base 92 (or a downward scale 78) serving as a reference. As the XZ head or the YZ head, an encoder head of a structure similar to the displacement sensor head disclosed in, for example, U.S. Pat. No. 7,561,280, can be used.

Further details regarding the liquid crystal exposure apparatus 10 can be found in U.S. Pat. No. 10,670,977, which is incorporated herein by reference.

### Example 2: Actuator System for Active Vibration Damping and Control Method

As the various stage assemblies of the exposure apparatus 10 (e.g., such as the mask stage device 14 and/or the substrate stage device 20) move in the step-and-scan operation described above, reaction forces developed by the various linear motors or other stage drivers can be transmitted to stationary structural elements of the apparatus. These reaction forces can cause the structural elements of the apparatus to vibrate, and in certain circumstances, can excite vibration at resonant mode frequencies of the structural elements. In certain embodiments, such vibrations can have a frequency of 2 Hz to 10 kHz, such as 5 Hz to 10 kHz, 100 Hz to 10 kHz, 100 Hz to 5 kHz, 10 kHz or less, 5 kHz or less, 3 kHz or less, 2 kHz or less, 1 kHz or less, 500 Hz or less, 300 Hz or less, 200 Hz or less, or 100 Hz or less. Such vibrations, particularly lower frequency vibrations (e.g., 500 Hz or less), can be particularly problematic on structural elements that support components or instruments that must be precisely aligned with the substrate P, and/or which serve as a position reference for the various stage assemblies, because the amplitudes of such vibrations tend to be relatively large.

One such structural element of the exposure apparatus 10 is the optical surface plate 18a which, as noted above, supports the projection optical system 16 and also functions as a reference for the substrate measurement system 70 used to perform position control of the substrate P. In certain embodiments, an actuator system can be employed to actively damp/reduce/control vibration of structural elements such as the optical surface plate 18a. In certain embodiments, the actuator system can comprise one or a plurality of actuators, one or a plurality of sensors, and a controller or control system (e.g., the main controller 100 or another system) that controls operation of the actuator(s) to damp out vibration of a structural element based on data from the sensor(s).

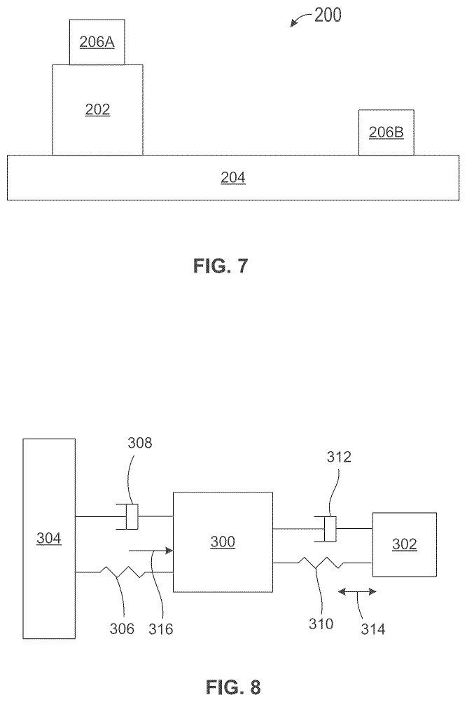

For example, FIG. 7 illustrates a representative example of an actuator system 200 comprising an actuator 202 mounted or coupled to a structural element 204 (also referred to as a structural member). The actuator system 200 can further comprise a plurality of sensors. A first sensor 206A is shown co-located with the actuator 202 (e.g., mounted to the actuator 202), and a second sensor 206B is shown remote from the actuator 202 and coupled to the structural element 204. The system can comprise any number of actuators and any number of sensors depending upon, for example, the shape of the structural element, the size of the structural element, the vibration mode(s) of the structural element to be damped, etc. The actuator(s) and/or sensor(s) can also be positioned anywhere on the structural element, such as its upper or lower surfaces, side surfaces, etc., or can be incorporated into the body of the structural element.

In certain embodiments, the actuator 202 can be any type of electric actuator with a suitably rapid response time, such as a voice coil motor (VCM), a piezo actuator, a linear motor, a reluctance actuator, etc.

In certain embodiments, the sensors 206A and 206B can be acceleration or vibration sensors such as accelerometers, velocity sensors such as moving coil or piezoelectric velocity receivers, position sensors such as linear potentiometers, capacity sensors, linear encoders, interferometers, or combinations thereof. In the following examples the sensors are configured as accelerometers, but other types of sensors can also be used.

FIG. 8 is a schematic diagram of a structural element 300 to be controlled/damped, along with an actuator system 302, represented as a mass-spring-damper system. The structural element 300 is shown coupled to an absolute reference (e.g., ground) 304 by a spring 306 and a damper 308. The actuator system 302, which for purposes of FIG. 8 represents an actuator and co-located accelerometer sensor, is coupled to the structural element 300 by a spring 310 and a damper 312. Motion of the structural element 300 relative to the ground 304 can be determined by the mass of the structural element, the spring constant of the spring 306, and the damping coefficient of the damper 308. The mass of the structural element 300 and the spring constant of the spring 306 can determine the vibration mode frequency of the structural element 300. In the example of an exposure apparatus, the structural element 300 can be analogous to the optical surface plate, the substrate stage, the mask stage, or other structures in the machine to which the actuator system 302 is coupled.

Motion of the actuator system 302 relative to the structural element 300 can be determined by the mass of the actuator system elements, the spring coefficient of the spring 310, and the damping coefficient of the damper 312. The mass of the actuator system 302 and the spring constant of the spring 310 can determine the vibration mode frequency of the actuator system 302. In certain embodiments, the vibration mode frequency of the actuator system can be the frequency at which the actuator or actuator system vibrates relative to the structural element while the actuator is in operation. In certain embodiments, designing the system such that the mode frequency of the actuator system 302 is less than the mode frequency of the structural element 300 can allow the actuator system 302 to damp structure mode vibrations of the structural element 300 more efficiently, but this is not required as demonstrated in subsequent examples herein.

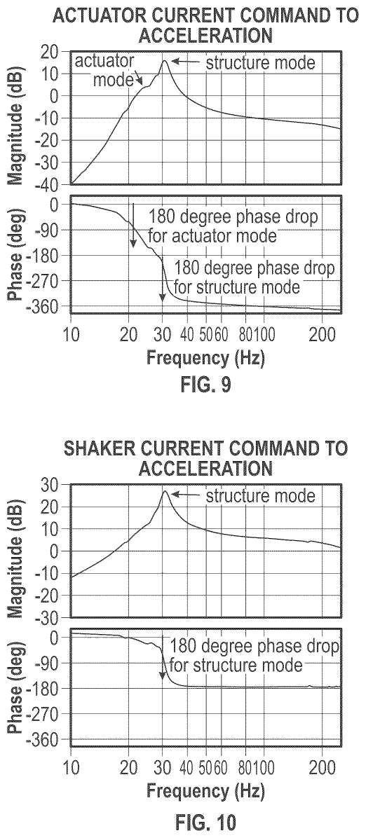

When the actuator of the actuator system 302 applies force to the structural element 300, the actuator pushes the actuator system 302 and the reaction force acts on the structural element 300. Double-headed arrow 314 indicates the relative motion of the actuator system 302 and the structural element 300 when the actuator is activated. FIG. 9 illustrates the open loop frequency response of the mass-spring-damper system of FIG. 8 when the disturbance force is applied by the actuator system 302. A structural mode vibration of the structural element 300 can be seen between 30 Hz and 40 Hz, and a mode vibration of the actuator system 302 can be seen between 20 Hz and 30 Hz. Phase drops of 180° can be seen for each mode.

FIG. 10 illustrates the open loop frequency response of the system of FIG. 8 when acted upon by a disturbance force (e.g., an impulse) applied to the structural element 300, such as by a shaker device separate from the actuator system and positioned between the ground 304 and the structural element 300. The force applied by the shaker device is represented by arrow 316 in FIG. 8. No vibration mode frequency of the actuator system is seen in FIG. 10.

In certain embodiments, vibration of the structural element 300 due to a disturbance force can be damped by operating the actuator system 302 according to a control scheme based on the vibration frequency or frequencies of the structural element to be damped, and including phase correction to compensate for one or more of amplifier bandwidth, sensor signal conditioning, and/or digital control time delay in the control system.

A representative embodiment of a feedback control system 400 is illustrated in FIG. 11. The mass-spring-damper system of the ground, the structural element, and the actuator system is represented at box 402, and referred to hereinafter as structural system. The control system 400 can further comprises an integration element 404 (also referred to as an integration and filter tool or module) and a filter controller or filter control element 406. A disturbance force d is shown acting on the structural system 402, which results in acceleration and motion (e.g., vibration) of the structural system 402. In certain embodiments, the dynamic response of the structural system 402 (e.g., the plant response) can be given by the transfer function P(s) in Equation 1 below, where m is the inertia of the vibration mode to be controlled, dᵣ is a damping ratio, and ωᵣ is the specified vibration frequency to be damped.

$$P ( s ) = \frac{{s}^{2}}{m ( {s}^{2} + 2 {d}_{r} {ω}_{r} s + {ω}_{r}^{2} )} \qquad Equation 1$$

Upon disturbance of the structural system 402 by the disturbance force d, the acceleration of the actuator can be determined by the co-located accelerometer sensor, and an acceleration signal can be provided to the integration element at block 404. In certain embodiments, the integration element 404 can integrate the acceleration signal received from the accelerometer sensor to obtain a position signal (e.g., the accelerometer sensor signal can be integrated twice by the integration element). The integration element 404 can also filter the accelerometer signal with one or more filters to select for a particular frequency or frequency band. For example, in certain embodiments the integration element 404 can filter the signal with a high-pass filter, which can reduce low-frequency drift of the signal from the accelerometer sensor. A representative transfer function Hₐ₂ₚ(s) of the integration element 404 representing the combination of integration of the accelerometer signal and a high-pass filter is given below in Equation 2, where dₐ is a damping ratio and ωₐ is the cutoff frequency of the high-pass filter.

$${H}_{a 2 p} ( s ) = \frac{1}{{s}^{2}} \cdot \frac{{s}^{2}}{{s}^{2} + 2 {d}_{a} {ω}_{a} s + {ω}_{a}^{2}} = \frac{1}{{s}^{2} + 2 {d}_{a} {ω}_{a} s + {ω}_{a}^{2}} \qquad Equation 2$$

The resulting position signal (also referred to as position data) can then be subtracted from a position command signal x(s) representative of the specified position of the structural system 402 at a summing junction 408. In certain embodiments, the position command x(s) (e.g., the specified position of the structural element) can be zero where no vibration/motion of the structural system 402 is desired. Subtraction of the position signal from the position command signal x(s) can yield a position error signal, which can be provided to the filter control element 406.

The filter control element 406 can determine a force command u, which can be transmitted to the actuator of the actuator system to cause the actuator to apply force to the structural element. In the following discussion u is referred to as a force command, but can also be a current command. In FIG. 11, the force command u is shown transmitted from the filter control element 406 and acting on the structural system 402 to damp vibration of the structural system.

In certain embodiments, the filter control element 406 can apply one or more of low-pass filters, bandpass filters, notch filters, and/or high-pass filters to the position error signal in order to generate the force command u. In a particular embodiment, the filter control element 406 can apply a combination of a low-pass filter including derivative control referred to hereinafter as a damping filter, a bandpass filter, and a notch filter. A representative transfer function C(s) of the filter control element 406 is given below in Equation 3, where H_{damp}(s) is the transfer function of the damping filter, H_{bandpass}(s) is the transfer function of the bandpass filter, and H_{notch}(s) is the transfer function of the notch filter. The filters can be applied to the input signal sequentially (e.g., in series). The individual transfer functions of the damping filter, the bandpass filter, and the notch filter are multiplied in Equation 3. It should be noted that the order of the filters in Equation 3 is only one example, and the filters can be applied to the input signal in any order.

$$C ( s ) = {H}_{d a m p} ( s ) \cdot {H}_{b a n d P a s s} ( s ) \cdot {H}_{notch} ( s ) \qquad Equation 3$$

In certain embodiments, the damping filter can include a derivative control term (also referred to as a damping control term or velocity control term) and a low-pass filter term. For example, in certain embodiments the transfer function of the damping filter H_{damp}(s) can be given by Equation 4 below, where k_{d} is a damping gain, k_{d}ωᵣs is the derivative control term (also referred to as a damping coefficient) of the transfer function, and the expression

$$\frac{1}{\frac{{s}^{2}}{{ω}_{r}^{2}} + 2 {d}_{r} \frac{s}{{ω}_{r}} + 1}$$

is the low-pass filter term.

$${H}_{d a m p} ( s ) = {k}_{d} {ω}_{r} s \cdot \frac{1}{\frac{{s}^{2}}{{ω}_{r}^{2}} + 2 {d}_{r} \frac{s}{{ω}_{r}} + 1} \qquad Equation 4$$

In certain embodiments, the low-pass filter can be underdamped (e.g., dᵣ<1), critically damped (e.g., dᵣ=1), or overdamped (e.g., dᵣ>1), depending upon the particular requirements of the system. In certain embodiments, the damping ratio dᵣ can be from 0.05 to 10, depending on the frequency or frequencies to be controlled. In certain embodiments, a larger damping ratio can result in wider control frequency range, but can also be associated with coupling between modes. In certain embodiments, the gain of the control system can be tuned by varying the damping gain k_{d} of the derivative control term of the damping filter.

In certain embodiments, the transfer function of the notch filter can be given by Equation 5, where d₁ and d₂ are damping ratios and ωₙ is a target frequency of the notch filter.

$${H}_{notch} ( s ) = \frac{\frac{{s}^{2}}{{ω}_{n}^{2}} + 2 {d}_{1} \frac{s}{{ω}_{n}} + 1}{\frac{{s}^{2}}{{ω}_{n}^{2}} + 2 {d}_{2} \frac{s}{{ω}_{n}} + 1} \qquad Equation 5$$

In certain embodiments, the target frequency won of the notch filter can be another vibration mode of the structural element different from the target mode frequency ωᵣ. For example, the frequency ωₙ of the notch filter can also be another vibration mode of the structure that is excited in response to the force command u of the actuator, but which is not necessarily a resonant mode frequency of the structural element.

In certain embodiments, the transfer function of the bandpass filter can be given by Equation 6, where d_{bp} is a damping ratio.

$${H}_{bandpass} ( s ) = \frac{2 {d}_{bp} \frac{s}{{ω}_{r}}}{\frac{{s}^{2}}{{ω}_{r}^{2}} + 2 {d}_{bp} \frac{s}{{ω}_{r}} + 1} \qquad Equation 6$$

In certain embodiments, the phase of the damping control force command u can be aligned at the target resonant frequency of the structural element to be damped. In certain embodiments, the phase alignment can be accomplished using the damping filter. For example, in certain embodiments the sum of the phase angles of the structural system transfer function P(s), the integration element transfer function Hₐ₂ₚ(s), and the filter control element transfer function C(s) can be set equal to zero, as shown below in Equation 7.

$$∠ P ( j {ω}_{r} ) + ∠ {H}_{a 2 p} ( j {ω}_{r} ) + ∠ C ( j {ω}_{r} ) = 0 \qquad Equation 7$$

In certain embodiments, the phase angle <C(jωᵣ) of the filter control element transfer function can be the sum of the phase angle <H_{damp}(jωᵣ) of the damping filter transfer function, the phase angle <H_{bandPass}(jωᵣ) of the bandpass filter transfer function, and the phase angle <H_{notch}(jωᵣ) of the notch filter transfer function. In certain embodiments, the phase angle <H_{bandPass}(jωᵣ) of the bandpass filter transfer function can be zero.

In certain embodiments, the phase lag θ of the system can be defined as the sum of the phase angle of the structural system transfer function <P(jωᵣ), the phase angle of the integration element transfer function <Hₐ₂ₚ(jωᵣ), and the phase angle of the notch filter transfer function <H_{notch}(jωᵣ), as given below in Equation 8.

$$θ = ∠ P ( j {ω}_{r} ) + ∠ {H}_{a 2 p} ( j {ω}_{r} ) + ∠ {H}_{notch} ( j {ω}_{r} ) \qquad Equation 8$$

In certain embodiments, it is possible to tune the damping filter to compensate for the phase lag θ of the system by setting the phase angle of the damping filter transfer function <H_{damp}(jωᵣ) equal to −θ as in Equation 9 below.

$$∠ {H}_{damp} ( j {ω}_{r} ) = - θ \qquad Equation 9$$

Applying Euler's Formula, phase correction can be applied to the transfer function H_{damp}(s) of the damping filter by using one of the two equations in the system of Equation 10 below.

$${e}^{- j θ} = cos θ - j sin θ = \{ \begin{matrix}{( cos θ + \frac{{ω}_{r} sin θ}{s} )}_{s = j {ω}_{r}} \\ {( - \frac{sin θ}{{ω}_{r}} s + cos θ )}_{s = j {ω}_{r}}\end{matrix} \qquad Equation 10$$

The result of multiplying the damping filter transfer function H_{damp}(s) (Equation 4) by each of the two equations in the system of Equation 10 is given below in Equation 11. In certain embodiments, where the phase angle of the damping filter transfer function H_{damp}(s) is equal to −θ as in Equation 9, the second equation in the system of Equation 11 below can avoid generation of a direct current (DC) term. Avoiding generation of a DC term can be advantageous in certain embodiments because a DC term can result in a constant position and/or constant force application by the actuator to the structural element, which can impede vibration damping.

$${H}_{damp} ( s ) = \{ \begin{matrix}{k}_{d} \cdot \frac{cos θ \cdot {ω}_{r} s + {ω}_{r}^{2} sin θ}{\frac{{s}^{2}}{{ω}_{r}^{2}} + 2 {d}_{r} \frac{s}{{ω}_{r}} + 1} \\ {k}_{d} \cdot \frac{- sin θ \cdot {s}^{2} + cos θ \cdot {ω}_{r} s}{\frac{{s}^{2}}{{ω}_{r}^{2}} + 2 {d}_{r} \frac{s}{{ω}_{r}} + 1}\end{matrix} \qquad Equation 11$$

Phase correction can also be applied using the bandpass filter in the manner described above, or using the notch filter(s). The total amount of phase correction can also be distributed among the damping filter, the bandpass filter, and/or the notch filter, depending upon the particular characteristics of the system.

The filter control element 406 can thus determine the force command u by filtering the position error signal received from the summing junction 408 with the phase-corrected damping filter H_{damp}(s) (e.g., applying the phase-corrected low-pass filter with derivative control), filtering the phase-corrected signal output of the damping filter with the bandpass filter H_{bandpass}(s), and filtering the output of the bandpass filter with the notch filter H_{notch}(s). The resulting force command u can then be transmitted to the actuator.

In certain embodiments, the control systems described herein can be configured to control/reduce vibrations of a structural element having any frequency within the control sampling rate limitations of the system and/or the amplifier bandwidth of the actuator. Thus, in certain embodiments the specified or target frequency ωᵣ of the damping filter can be 2 Hz to 10 KHz, such as 5 Hz to 10 kHz, 100 Hz to 10 kHz, 100 Hz to 5 kHz, 10 kHz or less, 5 kHz or less, 3 kHz or less, 2 kHz or less, 1 kHz or less, 500 Hz or less, 300 Hz or less, 200 Hz or less, or 100 Hz or less.

In other embodiments, the filter control element can implement other types of control such as proportional control and/or integral control in place of, or in addition to, the derivative control. For example, since damping force is the damping ratio of a system multiplied by velocity, the system can be damped using proportional control of velocity, integral control of acceleration, or derivative control of position.

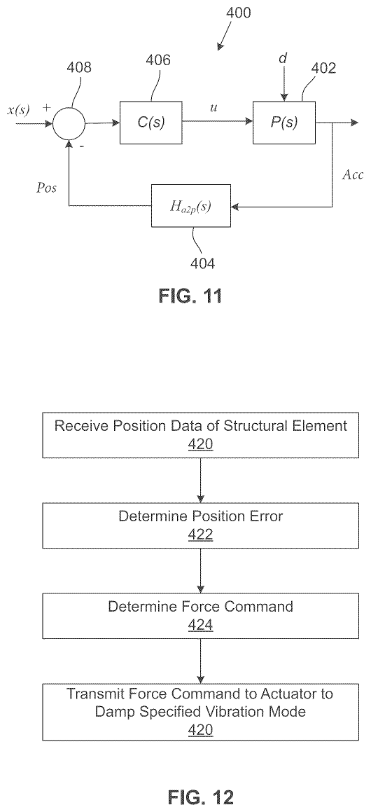

FIG. 12 illustrates a representative method of reducing vibration of a structural element with an actuator system and a control system as described herein. At process block 420 data of a position (e.g., a position signal) of a structural element of an exposure apparatus can be received (e.g., from the integration element after integrating and filtering the accelerometer signal). At process block 422, a position error signal can be determined relative to a specified position (or trajectory), such as by subtracting the position data/signal from the specified position. At process block 424, a force command can be determined based at least in part on a specified vibration mode frequency of the structural element to be damped and the position error signal. In certain embodiments, determining the force command can include one or more of filtering the position error signal with a low-pass filter (e.g., a low-pass filter including derivative control), filtering the position error signal with a bandpass filter, and/or filtering the position error signal with a notch filter as described herein. The above operations can be carried out in any combination and in any order. In certain embodiments, determining the force command can comprise applying phase correction to the position error signal, such as with the low-pass filter. At process block 426, the resulting force command can be transmitted to an actuator such that the actuator applies force to the structural element and damps vibration of the structural element at least at the specified vibration mode frequency of the structural element.

### Example 3: Control Systems and Methods for Damping Multiple Vibration Mode Frequencies

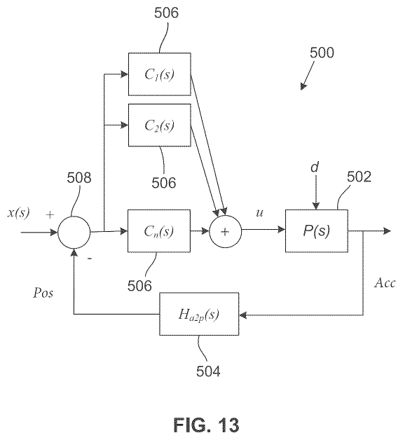

In certain examples, the control methodology described above can be adapted to control/damp vibrations of a structural element at multiple frequencies, such as multiple resonant mode frequencies of the structural element. FIG. 13 illustrates another embodiment of feedback control system 500 in which control for multiple frequencies/vibration modes is implemented in parallel. The feedback control system 500 illustrated in FIG. 13 has a block 502 representing the plant dynamics of the mass-spring-damper system to be controlled, which can exhibit a response to a disturbance force d given by the transfer function P(s) in Equation 1 above. The control system 500 can further comprise an integration element 504, which can operate as described above with reference to FIG. 11 and the transfer function Hₐ₂ₚ(s) given in Equation 2. After the position signal obtained by the integration element 504 is subtracted from the position command signal x(s), the resulting position error signal can be provided to a plurality of filter control elements 506 implemented in parallel. In certain embodiments, the number of filter control elements 506 can correspond to the number of vibration frequencies of the structural element to be controlled with the actuator system. For example, in certain embodiments each filter control element 506 can implement a combination of phase corrected damping filter control, bandpass filter control, and notch filter control as described above. Each filter control element 506 can be tuned to attenuate a particular target frequency, such as a particular vibration mode frequency of the structural element.

The outputs of the filter control elements 506 can be summed at a summing junction 508, resulting in a force command u transmitted to the actuator system as described above. The transfer function C(s) of the combined outputs of the filter control elements 506 can be defined as the sum of the transfer functions of each the individual filter control elements as given below in Equation 12, where N is the total number of filter control elements 506, and thereby the number of controlled vibration modes.

$$C ( s ) = {\sum }_{k = 1}^{N} {C}_{k} ( s ) \qquad Equation 12$$

In certain embodiments, one or a plurality of notch filters can be applied by each filter control element 506 to avoid excitation of other vibration frequencies. The transfer function of the notch filter(s) can be substantially as given above in Equation 5 for each target frequency ωᵣ. In certain embodiments, the notch filter transfer functions can be multiplied together such that the transfer function Cₖ(s) of each filter control element 506 can be given by Equation 13, where the transfer function H_{damp}(s) of the damping filter is substantially the same as given above in Equation 4, and the transfer function H_{bandpass}(s) of the bandpass filter is substantially as given above in Equation 6.

$${C}_{k} ( s ) = {H}_{damp , k} ( s ) \cdot {H}_{bandPass , k} ( s ) \cdot {\prod }_{{i = 1}_{i \neq k}}^{N} {H}_{notch , {ω}_{r , i}} ( s ) \qquad Equation 13$$

In certain embodiments, the sum of the filter control element outputs Cᵢ(jωₖ) can be approximately equal to Cₖ(jωₖ), as given below in Equation 14, because control of different vibration modes at the concerned frequencies can be decoupled due to the use of notch filters at ωₖ in the transfer function Cᵢ(s), for example where i=1 . . . . N and i≠k.

$$C ( j {ω}_{k} ) = {\sum }_{i = 1}^{N} {C}_{i} ( j {ω}_{k} ) \approx {C}_{k} ( j {ω}_{k} ) \qquad Equation 14$$

In certain embodiments, phase correction of the damping filter output of each filter control element can also be decoupled (e.g., determined independently of the other filter control elements). For example, because C(jωₖ) is approximately equal to Cₖ(jωₖ) as given in Equation 14 above, the sum of the phase angles in Equation 7 for the k^{th} filter control element at target frequency ωᵣ can be expressed as given below in Equation 15.

$$∠ P ( j {ω}_{r , k} ) + ∠ {H}_{a 2 p} ( j {ω}_{r , k} ) + ∠ {C}_{k} ( j {ω}_{r , k} ) = 0 \qquad Equation 15$$

The phase lag θₖ of the k^{th} filter control element can thus be expressed as given below in Equation 16.

$${θ}_{k} = ∠ P ( j {ω}_{r , k} ) + ∠ {H}_{a 2 p} ( j {ω}_{r , k} ) + {\sum }_{{i = 1}_{i \neq k}}^{{n}_{k}} ∠ {H}_{notch , {ω}_{r , i}} ( j {ω}_{r , k} ) \qquad Equation 16$$

With phase correction applied according to the second equation in the system of Equation 10 above, the phase-corrected transfer function of the damping filter of the k^{th} filter control element can be expressed as given below in Equation 17.

$${H}_{damp , k} ( s ) = {k}_{d , k} \cdot \frac{- s in {θ}_{k} \cdot {s}^{2} + cos {θ}_{k} \cdot {ω}_{r , k} s}{\frac{{s}^{2}}{{ω}_{r , k}^{2}} + 2 {d}_{r , k} \frac{s}{{ω}_{r , k}} + 1} \qquad Equation 17$$

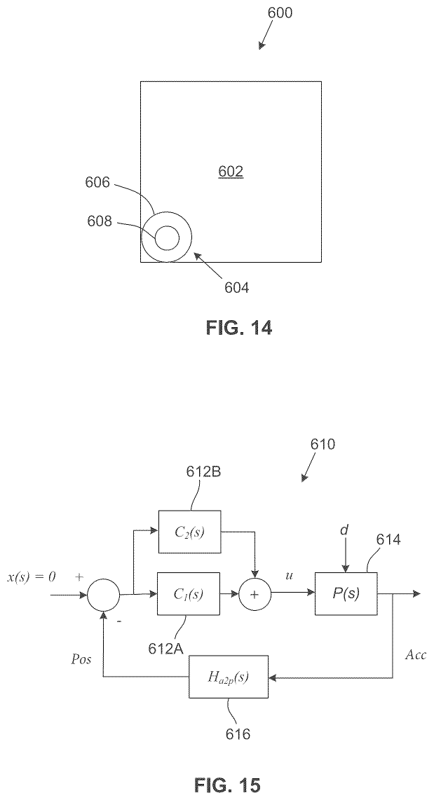

The control systems and methodology described above can significantly reduce the magnitude of vibrations at one or a plurality of vibration modes of a structure when a disturbance force is applied to the structure. The above control systems and methods can also significantly reduce the settling time of the system compared with the undamped response. For example, the control systems and methods described herein were applied to control/damp vibrations excited by an impulse applied to an experimental system 600 illustrated in FIG. 14. FIG. 14 is a top plan view of the system 600, which included a rectangular, metal plate member 602 supported at three corners, and an actuator system 604 mounted to the top surface of the plate member 602 at the unsupported corner. The actuator system 604 included an actuator configured as a voice coil motor (VCM) 606 and a sensor configured as an accelerometer 608 mounted on top of the VCM 606 (e.g., co-located with the VCM).

The actuator system 604 was controlled by the control system 610 illustrated in FIG. 15, which was configured according to the principles described above with reference to the control system of FIG. 13. The control system 610 included two filter control elements 612A and 612B implemented in parallel and configured to provide damping control of two vibration modes of the plate member 602. The control system 610 further included a system block 614 representing the dynamic response of the mass-spring-damper model of the system, and an integration element 616 configured similarly to those described above. Each filter control element 612A and 612B implemented a respective filter control scheme C₁(s) and C₂(s) including a phase-corrected damping filter (e.g., a phase-corrected low-pass filter including derivative control as described above), a bandpass filter, and one or a plurality of notch filters, as described above.

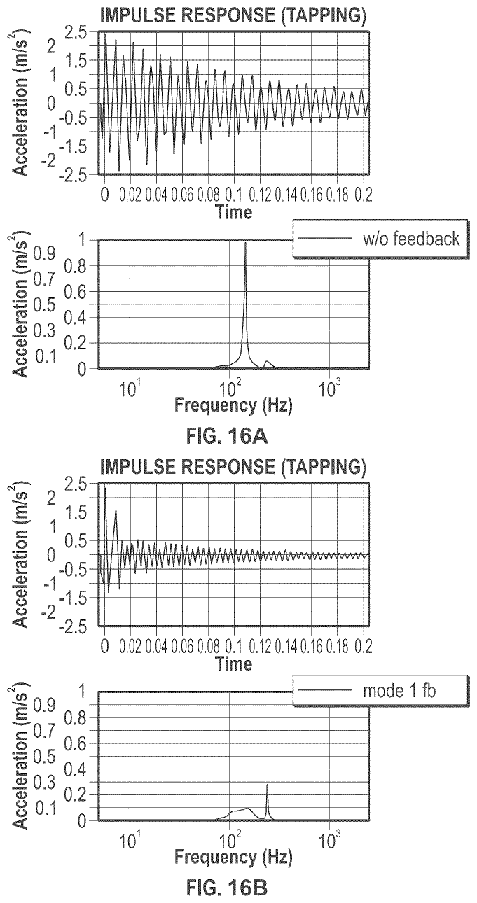

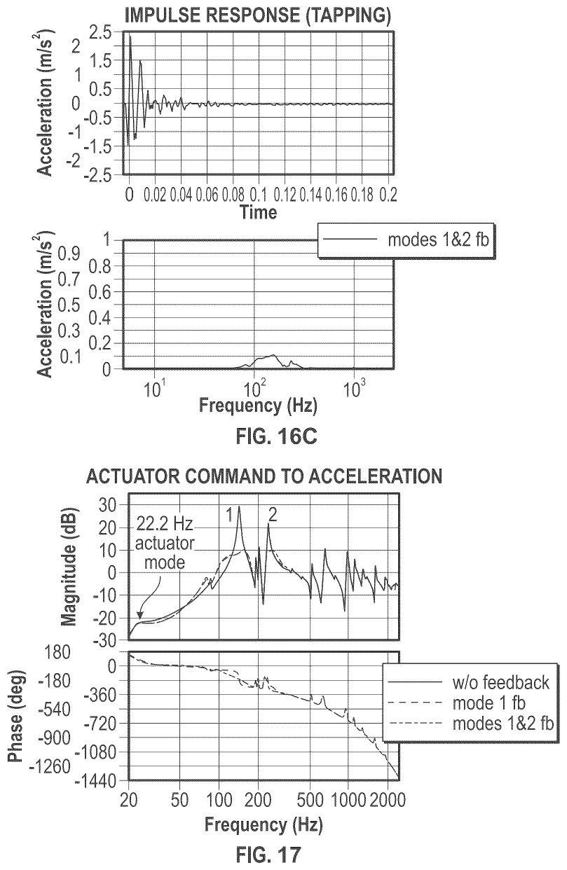

The upper graphs in FIGS. 16A-16C illustrate the acceleration as measured by the accelerometer 608 when the system 600 was excited by an impulse created by tapping on the plate member 602. The lower graphs in FIGS. 16A-16C illustrate the acceleration versus frequency of the system 600. The undamped/uncontrolled response of the system is illustrated (FIG. 16A), along with the response of the system when the control system 610 was operated to damp the first vibration mode (e.g., using filter control element 612A) (FIG. 16B) and the response when the control system was operated to damp both the first and the second vibration modes (e.g., using both filter control elements 612A and 612B) (FIG. 16C). FIG. 17 is a Bode plot illustrating the magnitude and phase of the frequency response of the system without feedback control, with damping control of the first vibration mode, and with damping control of both the first and second modes. As can be seen in FIGS. 16A-16C and 17, the control system 610 reduced acceleration of the plate member vibrations nearly to 0 m/s² within approximately 0.1 seconds and significantly reduced the peak magnitude of the vibrations by approximately 20 dB for the first mode and approximately 10 dB for the second mode.

The control systems and methods described herein can also be configured to operate with sensor feedback from one or a plurality of accelerometer sensors that are remote from the actuator. Stated differently, one or a plurality of accelerometers of the system need not be co-located with the actuator. In such configurations, the phase correction applied by the filter control element(s) operating on signals from the remote accelerometers can be adjusted accordingly to account for, for example, the difference in phase angle arising from the distance between the accelerometer and the actuator, and/or the phase difference associated with modal deformation of the structure at different vibration modes.

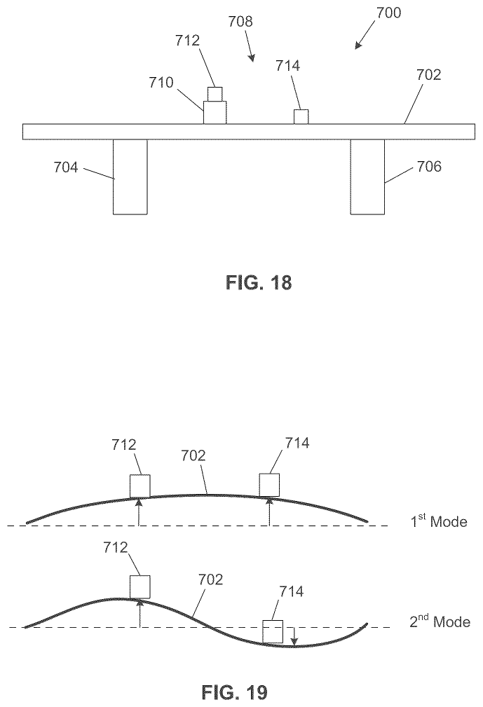

For example, FIG. 18 is a side elevational view illustrating another experimental system 700, which included a metal beam member 702 of rectangular cross-section clamped to two support members 704 and 706 spaced apart from each other along the length of the beam member 702. The system 700 further included an actuator system generally indicated at 708 mounted to the top surface of the beam member 702 between the support members 704 and 706. The actuator system 708 included an actuator configured as a VCM 710, and two accelerometer sensors 712 and 714. The accelerometer sensor 712 was mounted on top of the VCM 710, and the other accelerometer sensor 714 was mounted directly to the beam member 702 at a location spaced apart from the VCM 710. The actuator system 708 was controlled by a control system similar to the control system 610 illustrated in FIG. 15.

FIG. 19 schematically illustrates the first and second vibration modes of the beam member 702, and the relative location of the two accelerometer sensors 712 and 714. As can be seen from FIG. 19, in the first mode the two sensors 712 and 714 are in phase, and in the second mode the two sensors are 180° out of phase. Thus, the damping filter of each filter control element was configured to apply phase correction based on the associated accelerometer signal so that the VCM acted in the correct direction to damp vibration of the beam member in both the first and second vibration modes.

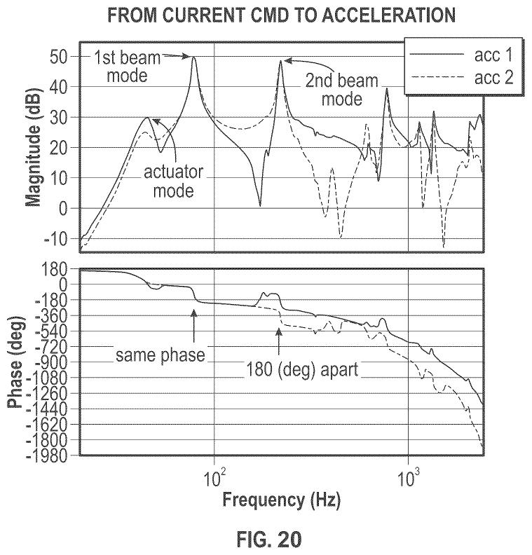

FIG. 20 is a Bode plot illustrating the magnitude and phase of the open loop frequency response of the system 700 as measured by the accelerometers 712 and 714. A peak corresponding to the first beam vibration mode can be seen at approximately 80 Hz, and a peak corresponding to the second beam mode can be seen at approximately 210 Hz. As can be seen in the phase plot, the two accelerometer signals are in phase at the first mode frequency, and 180° at the second mode frequency.

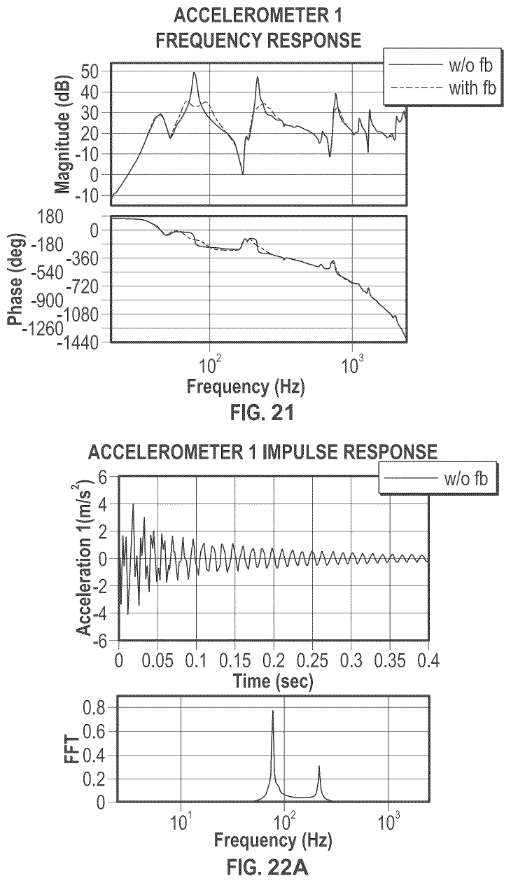

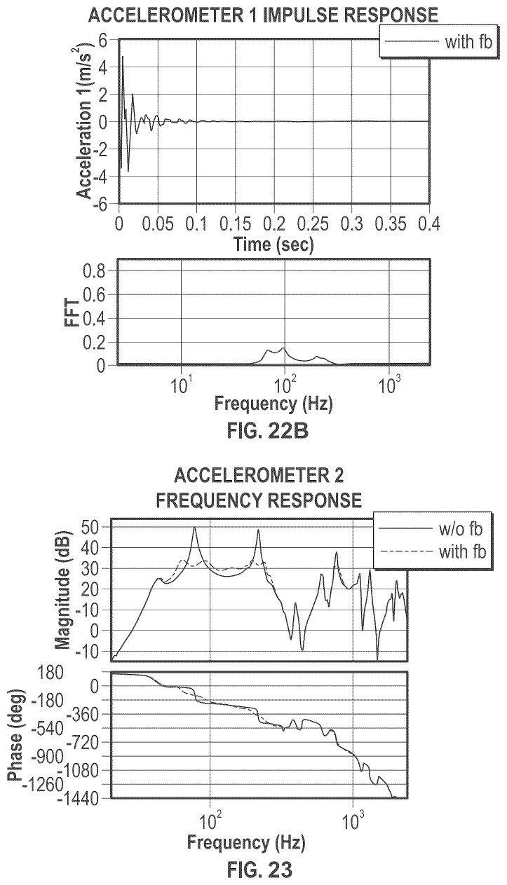

FIG. 21 is a Bode plot showing the open loop frequency response of the system 700 and the frequency response applying control with position data derived from the first accelerometer 712 co-located with the VCM 710. FIGS. 22A and 22B include plots of acceleration versus time and fast Fourier transforms (FFT) illustrating the open loop impulse response of the system (FIG. 22A) and the impulse response of the system applying control with position data derived from the first accelerometer 712 (FIG. 22B). Both plots show the relatively rapid damping of oscillations and the relatively lower peak magnitude of the first and second mode frequencies when damped with the actuator system.

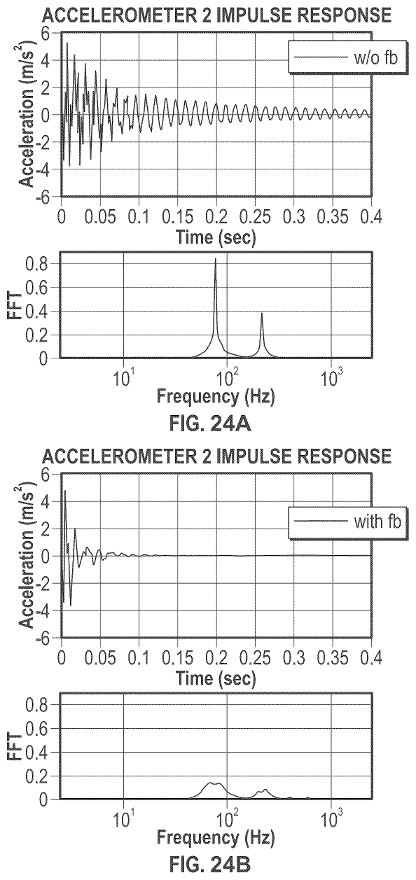

FIG. 23 is a Bode plot showing the open loop frequency response of the system 700 and the frequency response applying control with position data derived from the second accelerometer 714, which is remote from the VCM 710. FIGS. 24A and 24B include plots of acceleration versus time and fast Fourier transforms illustrating the open loop impulse response of the system (FIG. 24A) and the impulse response of the system applying control with position data derived from the second accelerometer 714 (FIG. 24B). FIGS. 23 and 24A-24B also show a relatively rapid damping of oscillations and the relatively lower peak magnitudes of the first and second mode frequencies when damped with the actuator system. Based on phase lag information from the Bode plots, the phase correction terms of the damping filters of each filter control element can be tuned to control the actuator system using either the first accelerometer 712, the second accelerometer 714, or both. Accordingly, control can be implemented using data from sensors co-located with the actuator, or positioned remotely from the actuator elsewhere in the system, to tune the filters of the various filter control elements.

### Example 4: Control System and Method for Damping Vibration Mode Frequencies Below Vibration Mode Frequency of Actuator System

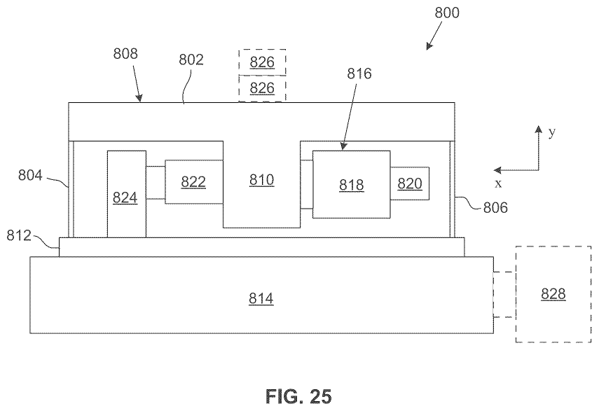

In certain embodiments, using the filters and phase correction methods described herein, the disclosed control systems can also be configured to damp structural vibration modes having a lower frequency than the vibration mode frequency of the actuator system (e.g., the frequency at which the actuator vibrates relative to the structural element to which it is mounted when the actuator is active). For example, FIG. 25 illustrates an experimental structural system 800 which was controlled using a control system configured similarly to the control system 610 of FIG. 15. The structural system 800 included a T-shaped metal member 802 supported at both ends by flexure members 804 and 806. The T-shaped metal member 802 included a first, main portion 808 and a second portion 810 at or near the center of the main portion 808 and extending downwardly from the main portion 808 and perpendicular to the main portion 808. The flexure members 804 and 806 were coupled to a base member 812, which was coupled to a bench member 814 (e.g., an optical bench). The flexure members 804 and 806 suspended the T-shaped metal member 802 above the base member 812.

An actuator system 816 including a VCM 818 and an accelerometer 820 was coupled to the second portion 810 of the T-shaped metal member 802, and was configured to act in the x-direction. The accelerometer 820 was coupled to the housing of the VCM 818 (stated differently, the accelerometer was co-located with the VCM). A shaker in the form of a VCM 822 was positioned between the second portion 810 of the T-shaped metal member 802 and a bracing member 824 secured to the base member 812. The shaker VCM 822 was configured to impart an impulse disturbance force to the system 800. The vibration mode frequencies of the system were changed by adding weights 826 to the T-shaped metal member 802.

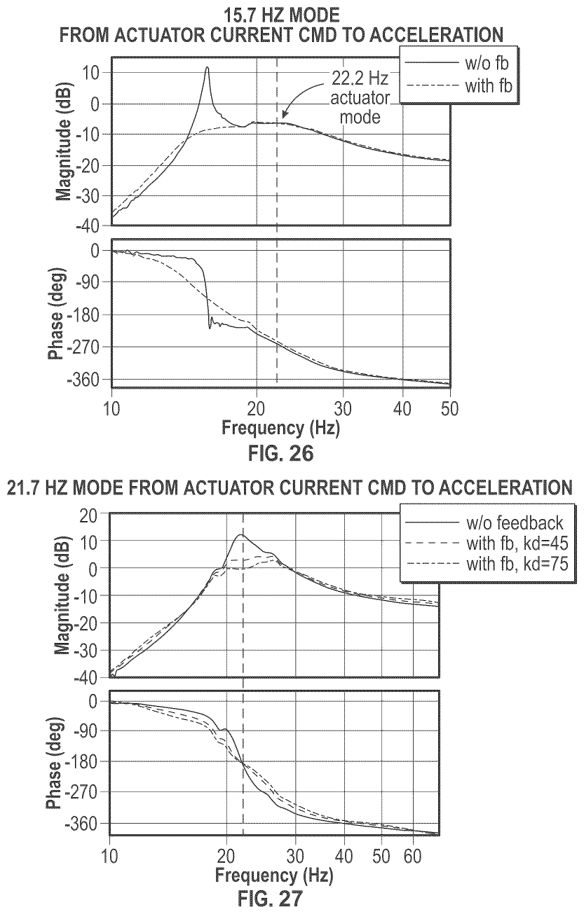

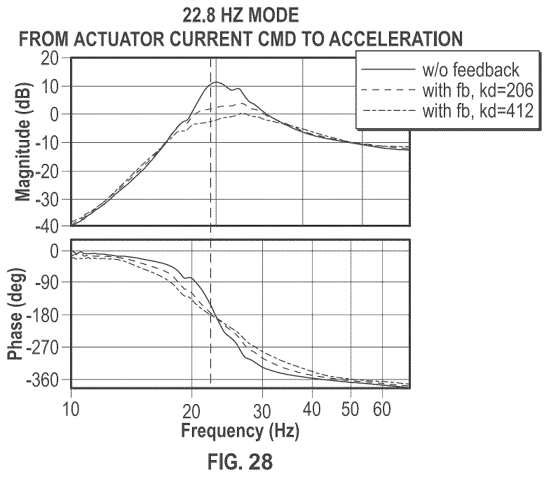

In one configuration, the system 800 was configured to vibrate at a 15.7 Hz resonance mode. The system also displayed several other vibration mode frequencies below 100 Hz, including at 21.7 Hz, 22.8 Hz, 30.5 Hz, and 44 Hz. The vibration mode frequency of the actuator system 816 relative to the T-shaped metal member 802 was 22.2 Hz. Thus, the 15.7 Hz mode and the 21.7 Hz mode of the structure were below the mode frequency of the actuator system 816, and the 22.8 Hz mode was only slightly above the actuator system mode frequency. Bode plots of the damped and undamped frequency response of the system 800 showing the 15.7 Hz mode, the 21.7 Hz mode, and the 22.8 Hz mode of the system are presented in FIGS. 26-28, respectively. The results of control using different values of the damping gain k_{d} are given in FIGS. 27 and 28. As can be seen from FIGS. 26-28, by adjusting the damping gain k_{d} of the damping filter (Equation 17), the control system could be tuned to effectively damp the mode frequencies of the structural system that were below the vibration mode frequency of the actuator system 816. In particular, a k_{d} value of 75 reduced the peak magnitude of the 15.7 Hz mode by approximately 20 dB as compared to the open loop response, and reduced the magnitude of the 21.7 Hz mode by 10-15 dB. A k_{d} value of 412 reduced the peak magnitude of the 22.8 Hz mode by approximately 15 dB. The settling time of each vibration mode was also reduced to 0.2 seconds or less, compared to up to 5 seconds for the 15.7 Hz mode in an undamped system.

### Example 5: Control System and Method for Damping Vibration Mode Frequencies from External Source Using Peak Filter Control

In certain embodiments, the control systems described herein can also be configured to damp/control vibration transmitted to the structural system from a remote disturbance force. For example, in certain embodiments one or a plurality of the filter control elements of the system can include a peak filter (e.g., a band-pass filter) instead of, or in addition to, the damping filters described above. For example, in certain embodiments one or a plurality of filter control elements of a control system can implement damping filter control as described above, and one or a plurality of filter control elements can be configured to implement peak filter control as described below.

In certain embodiments, the peak filter can be tuned to pass the target vibration frequency or frequencies to be damped. In certain embodiments, the peak filter can be configured to apply phase correction as described above to compensate for phase lag associated with, for example, remote positioning of the accelerometer sensor, time delay of the actuator amplifier, signal conditioning, and/or time delay of digital control. In certain embodiments, phase correction can also allow the peak filter to damp vibrations of the structural system that are below the mode frequency of the actuator system, as described above. In certain embodiments, peak filters as described herein can have less influence on higher frequency dynamics than damping filter control, and thus can be implemented in combination with a damping filter to control lower frequency modes with limited coupling between damped vibration modes.

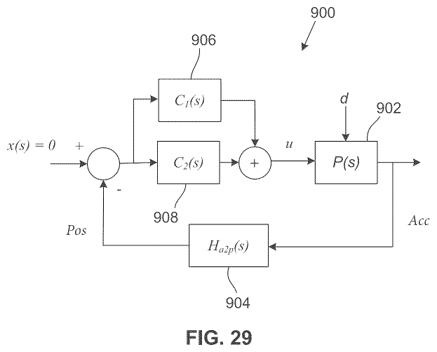

For example, FIG. 29 illustrates an embodiment of a control system 900 configured to implement a peak filter control channel in parallel with a damping filter control channel. The control system 900 includes a system block 902 configured to represent the dynamic response of the structural system to be controlled, an integration element 904 configured similarly to those described above, and two filter control elements 906 and 908 implemented in parallel. The filter control element 906 can implement phase-corrected damping filter control C₁(s), for example, based on the transfer function of Equation 17 above. The filter control element 908 can implement a combination of phase-corrected peak filter control, bandpass filter control, and notch filter control based on the transfer function C₂(s) below in Equation 18.

$${C}_{2} ( s ) = {H}_{peak} ( s ) \cdot {H}_{bandPass} ( s ) \cdot {\prod }_{k = 1}^{n} {H}_{notch , k} ( s ) \qquad Equation 18$$

In certain embodiments, the transfer function Hₚₑₐₖ(s) of the peak filter can be given by Equation 19 below, where kₐ is the damping gain, dₚ is a damping ratio, and op is the target frequency of the peak filter.

$${H}_{peak} ( s ) = {k}_{a} \cdot \frac{cos θ \cdot {ω}_{p} s + sin θ \cdot {ω}_{p}^{2}}{\frac{{s}^{2}}{{ω}_{p}^{2}} + 2 {d}_{p} \frac{s}{{ω}_{p}} + 1} \qquad Equation 19$$

In certain embodiments, the transfer function H_{bandpass}(s) of the bandpass filter control can be similar to Equation 6 above, and the transfer function(s) H_{notch}(s) of the notch filter(s) can be similar to Equation 5 above. The phase lag θ of the system can be determined according to Equation 16 above. The number of notch filters included can depend on the number of vibration modes of the structural element to be damped, and can take into account both resonant frequencies of the structure and/or vibration modes of the structure excited by the actuator when damping other modes. In certain embodiments, the peak filter can include derivative control, proportional control, and/or integral control similar to the damping filters described above.

In a representative working example, the control system 900 of FIG. 29 was used to control/damp vibration of the structural system 800 of FIG. 25 when an impulse force was applied to the bench member 814 by a shaker VCM 828 shown in dashed lines. In the present working example, the VCM 822 was removed from the system. The VCM 828 was offset from the structural system 800 along the z-axis (e.g., in a direction into the plane of the page in FIG. 25). The impulse disturbance force applied to the bench member 814 by the VCM 828 resulted in a 19.5 Hz vibration mode of the bench member 814, and a 45 Hz vibration mode of the structural system 800. The 45 Hz vibration mode of the structural system 800 was damped using the filter control element 906 implementing phase-corrected damping filter control, and the 19.5 Hz vibration mode of the optical bench was damped using the filter control element 908 implementing phase-corrected peak filter control.

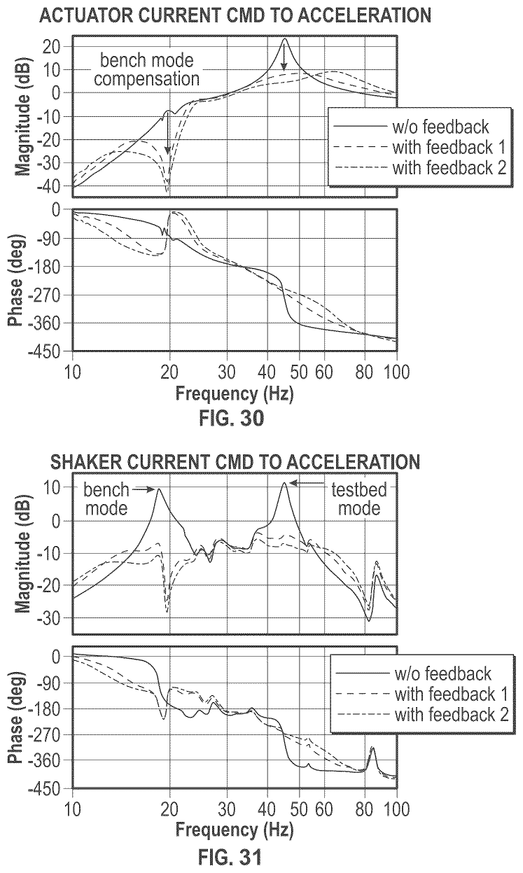

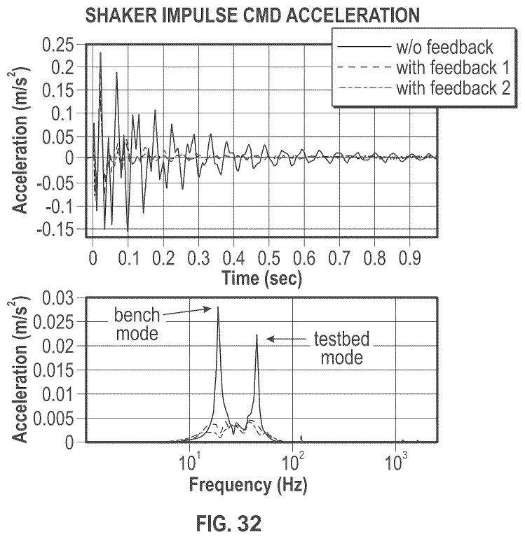

The frequency response of the system 800 when controlled by the control system 900 is shown in the Bode plots in FIGS. 30 and 31. FIG. 30 illustrates the frequency response of the system 800 when excited by a current command from the actuator. FIG. 31 illustrates the frequency response of the system 800 when excited by the shaker VCM 828 coupled to the bench member 814. FIGS. 30 and 31 illustrate the open loop response of the system, the response when applying feedback control through the damping filter control element 906, and the response applying both the damping filter control element 906 and the peak filter control element 908. The line labeled “feedback 1” in FIGS. 30-32 is the response of the system where the peak filter was tuned such that kₐ=160, and in the line “feedback 2” kₐ=300. As can be seen from FIGS. 30 and 31, the filter control elements 906 and 908 significantly reduced the peak magnitudes of the bench member mode and the structural system mode as compared to the undamped system at both kₐ values. Referring to FIG. 32, both control schemes also reduced the measured acceleration associated with both modes, and reduced the settling time of the structural system 800 to less than 0.3 seconds.

### Example 6: Control Systems and Methods Using Multiple Remotely Located Sensors

In certain embodiments, the actuator system can include multiple sensors located at different locations on the structural system to be controlled, and data from a plurality of such sensors can be used in multiple control loops to damp multiple vibration modes of the structure. Control systems for such structures can include a plurality of control loops including filter control elements with feedback from different sensors in the structural system. In certain embodiments, the outputs of the various control loops can be summed to generate the force command for the actuator system.

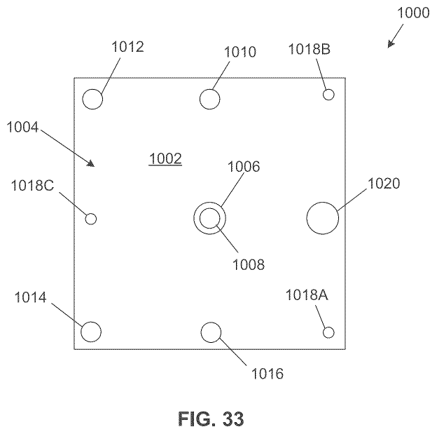

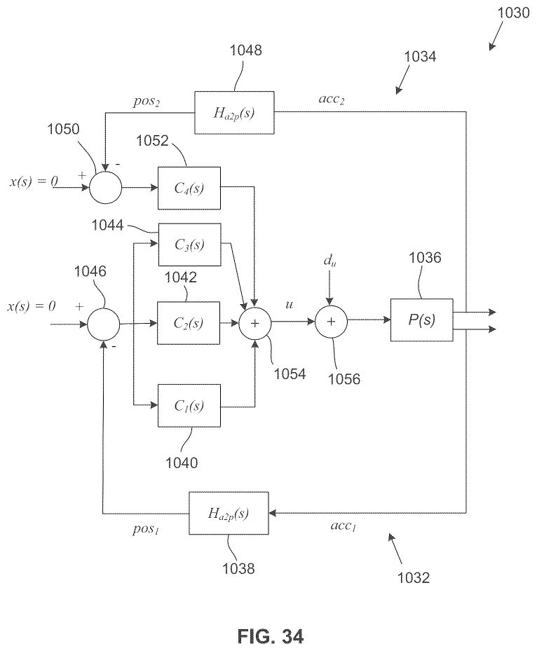

For example, FIG. 33 illustrates a top plan view of a structural system 1000 including a rectangular plate member 1002 and an actuator system generally indicated at 1004. The actuator system 1004 included a VCM 1006, and a plurality of accelerometer sensors 1008, 1010, 1012, 1014, and 1016. In the illustrated configuration, the accelerometer sensor 1008 was co-located with the VCM 1006, and the remaining sensors were arrayed around the edges of the plate member 1002. The accelerometer 1010 was positioned near the center of the top edge of the plate member, and the accelerometer 1016 was positioned near the center of the bottom edge of the plate member in FIG. 33. The accelerometer 1012 was located at the top left corner and the accelerometer 1014 was located at the bottom left corner. The plate member 1002 was coupled to and suspended above an optical bench or another support by three support members 1018A-1018C in the triangular arrangement shown. A shaker configured as a VCM 1020 was positioned along the middle of the right-side edge of the plate member between the support members 1018A and 1018B.

In certain embodiments, depending on the placement of an accelerometer sensor, it may sense a particular vibration mode or modes of a structural system, and not others depending on whether the position of the sensor coincides with node(s) of a vibration mode or modes. For example, the plate member 1002 as configured in FIG. 33 displayed four relatively low-frequency vibration modes when excited by an impulse disturbance force from the actuator VCM 1006 and/or from the shaker VCM 1020. The first mode was at 61 Hz, the second mode was at 96 Hz, the third mode was at 165 Hz, and the fourth mode was at 282 Hz. The accelerometer 1008 positioned atop the VCM 1006 detected the second, third, and fourth modes well, but did not have a strong signal from the first mode. The accelerometer 1014 provided a clear signal of the first vibration mode.

The various vibration modes in such a structural system can be controlled with a control system implementing the damping filter and/or peak filter control architectures described herein in multiple, parallel control loops, where each control loop is configured to damp vibrations at one or a plurality of modes based on feedback from a sensor positioned to sense vibration of the structure at the target mode or modes of the control loop. For example, FIG. 34 illustrates a representative control system 1030 including two control loops (also referred to as control channels), which can be used to control vibrations of the four modes of the structure 1000 of FIG. 33. A first control loop is generally indicated at 1032, and a second control loop is generally indicated at 1034. The control system includes a system block 1036 representing the dynamic response of the structural system 1000. The first control loop 1032 further includes an integration element 1038, and three filter control elements 1040, 1042, and 1044 implemented in parallel. A position signal outputted from the integration element 1038 is subtracted from the position command signal x(s) to obtain a position error signal, which is inputted to the filter control elements 1040-1044. The filter control elements 1040-1044 can be configured to implement filter control based on transfer functions C₁(s), C₂(s), and C₃(s). The filter control elements can be configured to implement phase-corrected damping filter control as described above with reference to Equations 13-17, and/or phase-corrected peak filter control as described above with reference to Equations 18 and 19. The filter control elements 1040-1044 can be tuned for a particular target mode frequency of the structural system 1000. In a particular embodiment, the filter control elements 1040-1044 were configured to control the second, third, and fourth modes of the structural system 1000, respectively.

The second control loop 1034 can also include an integration element 1048, and a summing junction 1050 that outputs a position error signal to a filter control element 1052 after subtracting the position signal of the integration element from the position command signal x(s). The filter control element 1052 can implement filter control based on a transfer function C₄(s), which can include phase-corrected damping filter control similar to Equations 13-17 above, or phase-corrected peak filter control as described with reference to Equations 18 and 19, and tuned for a particular target mode frequency of the structural system 1000. In a particular embodiment, the filter control element 1052 of the second control loop was tuned to attenuate the first vibration mode of the structural system 1000.

The outputs of the filter control elements 1040-1044 of the first control loop 1032 can be summed with the output of the filter control element 1052 of the second control loop 1034 at a summing junction 1054 to provide a command signal u, which is provided to the actuator system. A disturbance force dᵤ is represented as being combined with the force command signal at a summing junction 1056 before the command signal is provided to the structural system block 1036.

When used to attenuate vibration of the structural system 1000 of FIG. 33, the first control loop 1032 can operate using acceleration data obtained from the accelerometer 1008 co-located with the VCM 1006, and can be configured to control the second, third, and fourth vibration modes of the plate member 1002. The second control loop 1034 can be configured to utilize acceleration data obtained from the accelerometer 1014 to control the first vibration mode of the plate member 1002. Thus, in the illustrated embodiment a first accelerometer signal acc₁ from the accelerometer 1008 is transmitted to the integration element 1038 of the first control loop 1032. The integration element 1038 outputs a position signal pos₁ to the summing junction 1046, which is subtracted from the position command signal x(s) to obtain the position error signal provided to the filter control elements 1040-1044. An equation for the first accelerometer signal acc₁ is given below in Equation 20, where

$${P}_{acc 1} = \frac{acc 1}{u} and {P}_{pos 1} = {H}_{a 2 p} {P}_{acc 1} = \frac{pos 1}{u} . \\ \frac{acc 1}{{d}_{u}} = \frac{{P}_{acc 1}}{1 + {P}_{pos 1} ( {C}_{1} + {C}_{2} + {C}_{3} ) + {P}_{pos 2} {C}_{4}} \qquad Equation 20$$

For the second control loop 1034, a second accelerometer signal acc₂ from the accelerometer 1014 is transmitted to the integration element 1048 of the second control loop. The integration element 1048 outputs a position signal pos₂ to the summing junction 1050, where it is subtracted from the position command signal x(s) to obtain a position error signal. The position error signal is provided to the filter control element 1052. An equation for the second accelerometer signal acc₂ is given below in Equation 21, where

$${P}_{acc 2} = \frac{acc 2}{u} and {P}_{pos 2} = {H}_{a 2 p} {P}_{acc 2} = \frac{pos 2}{u} . \\ \frac{acc 2}{{d}_{u}} = \frac{{P}_{acc 2}}{1 + {P}_{pos 1} ( {C}_{1} + {C}_{2} + {C}_{3} ) + {P}_{pos 2} {C}_{4}} \qquad Equation 21$$

Equations 20 and 21 relate to how the feedback filter controllers and sensors are coupled in the closed-loop system. In certain embodiments, Equations 20 and 21 can be used in offline control design synthesis and simulation in the frequency domain before actual implementation of the control system.

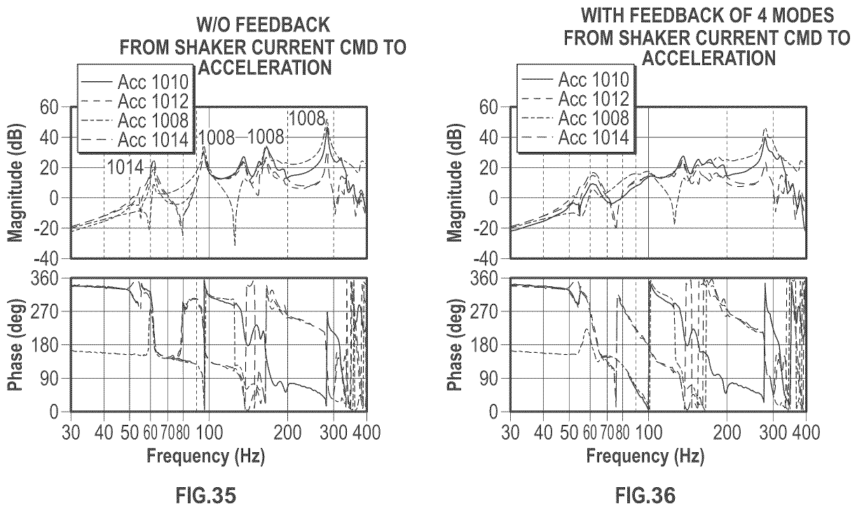

FIG. 35 illustrates a Bode plot of the open loop frequency response of the system 1000 of FIG. 33 when excited by an impulse from the shaker VCM 1020. Peaks can be seen at the 61 Hz mode, the 96 Hz mode, the 165 Hz mode, and the 282 Hz mode. As indicated in FIG. 35, the accelerometer 1014 provided a clear signal of the 61 Hz mode, while the accelerometer 1008 provided a clear signal of the second, third, and fourth modes. FIG. 36 is a Bode plot of the frequency response of the system applying control of all four modes with the actuator system based on force commands from the control system 1030 of FIG. 34. Significant reductions in peak magnitude can be seen for each vibration mode in FIG. 36.

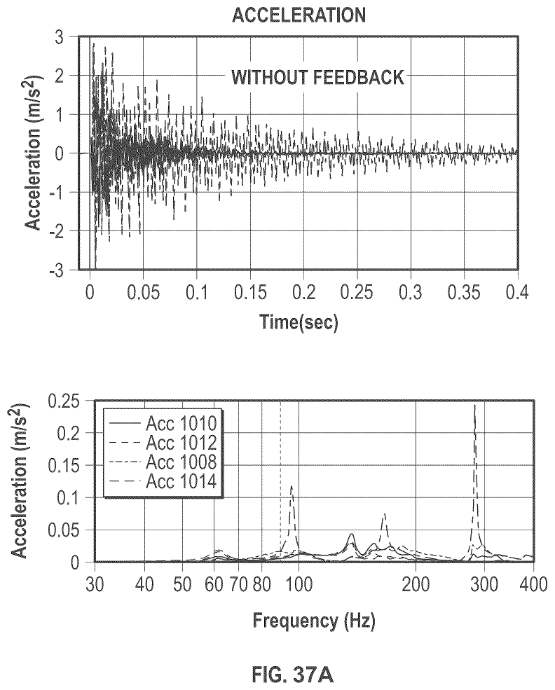

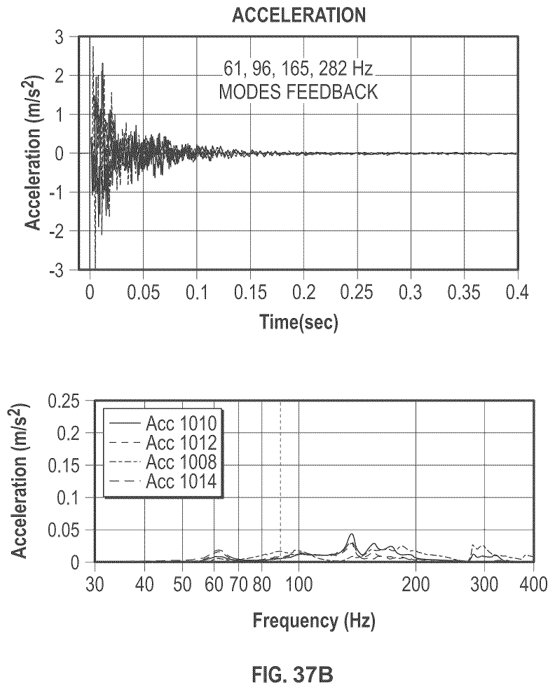

Plots of acceleration versus time (top) and acceleration versus frequency (bottom) for the system 1000 are illustrated in FIGS. 37A and 37B. As can be seen in FIGS. 37A and 37B, using the actuator system 1004 controlled according to the control system of FIG. 34, each of the four controlled vibration modes of the structural system 1000 is damped nearly completely at 0.2 seconds after impulse excitation. This is a significant improvement over the undamped system, in which vibrations persist for one second or longer. Thus, the disclosed control systems can be used to significantly reduce the settling time of multiple vibration modes of a structural system, and vibrations at frequencies below 300 Hz, such as below 100 Hz in particular.

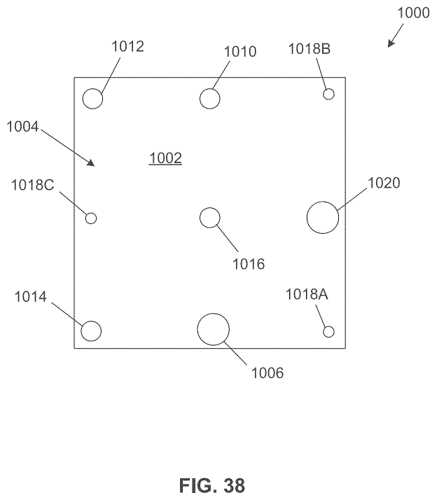

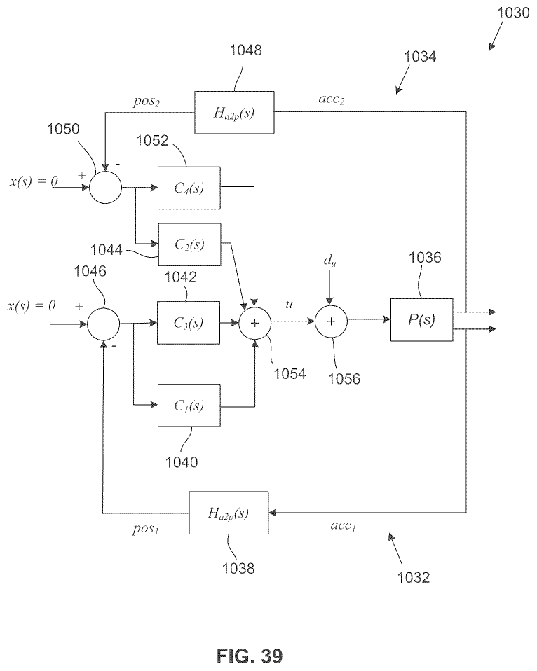

The control loops of the control system 1030 can be configured in a variety of ways depending upon factors such as the shape, size, etc., of the structural system, the positioning of the accelerometer sensors 1010-1016, the location of the actuator 1006, the location of the shaker VCM, and the like. FIG. 38 illustrates another arrangement of four accelerometers 1010-1016, the actuator VCM 1006, and the shaker VCM 1020 on the plate member 1002. The accelerometer 1008 is shown removed from the actuator VCM 1006. The configuration of FIG. 38 displays four vibration modes of the plate member 1002 similar to those described above with reference to FIG. 33. In certain embodiments, the accelerometer 1014 provides a clear signal of the first and third vibration modes, and the accelerometer 1010 provides a clear signal of the second and fourth modes. Accordingly, the control system of FIG. 34 can be rearranged as shown in FIG. 39 such that the signal acc₁ from the accelerometer 1010 is fed back to the filter control elements 1040 and 1044, which are arranged in parallel in the first control loop 1032 and configured to generate control signals to attenuate vibration at the first and third modes. The signal acc₂ from the accelerometer 1014 is fed back to the filter control elements 1042 and 1052 arranged in parallel in the second control loop 1034 and configured to generate control signals to attenuate the second and fourth modes. Thus, the control systems described herein can include any number of control loops implementing any number of filter control elements depending upon the number of vibration modes to be controlled, the number and positioning of accelerometers detecting the target modes of the system, etc.

### Example 7: Structural System Dynamics Model and Placement of Sensors and Actuators

In certain embodiments, the magnitude of a force command for suppressing/controlling vibration of a structural system at a particular vibration mode frequency can be estimated based on the magnitude of the vibration at that mode frequency. In certain embodiments, the vibration magnitude of a particular mode can be measured experimentally, and/or determined using any of a variety of models of the system and its frequency response, such as finite element analysis (FEA) models, state space models, and the like. In certain embodiments, the displacement of the structural system at a first location in response to a force applied to the structural system at a second location can be determined from such a system model. Information from such models and/or measurements of the system can be used to select the location of the actuator and/or the location of one or a plurality of accelerometer sensors in order to effectively damp one or a plurality of selected vibration modes of the structure.

For example, in a representative example the dynamics of a structural system such as the plate member 1002 of FIG. 38 can be transformed into a decoupled modal coordinate space. The dynamics of the structural system can be given by the expression below in Equation 22, where M is a mass matrix of the FEA model, K is a stiffness matrix of the FEA model, and v is a displacement vector.

$$M \ddot{v} + Kv = 0 \qquad Equation 22$$

Solution of the eigenvalue expression below in Equation 23, where ω² is an eigenvalue and ϕ is an eigenvector yields ωₖ², a square of the natural frequency of the k^{th} mode (a scalar quantity), and ϕₖ, a vector representative of the mode shape of the of the k^{th} mode, where k=1, . . . . N and N is three times the number of nodes in the three-dimensional FEA model.

A mode shape matrix M_{modal} for the FEA model can be as given below in Equation 23, where Φ=[Φ₁ . . . Φ_{N}] and mₖ is the model mass for the k^{th} mode.

$${Φ}^{T} M Φ = {M}_{modal} = [ \begin{matrix}{m}_{1} & 0 & 0 \\ 0 & ⋱ & 0 \\ 0 & 0 & {m}_{N}\end{matrix} ] \qquad Equation 23$$

A modal stiffness matrix K_{modal} for the FEA model can be as given below in Equation 24, where the modal stiffness for the k^{th} mode is kₖ=mₖωₖ².

$${Φ}^{T} K Φ = {K}_{modal} = [ \begin{matrix}{k}_{1} & 0 & 0 \\ 0 & ⋱ & 0 \\ 0 & 0 & {k}_{N}\end{matrix} ] = [ \begin{matrix}{m}_{1} {ω}_{1}^{2} & 0 & 0 \\ 0 & ⋱ & 0 \\ 0 & 0 & {m}_{N} {ω}_{N}^{2}\end{matrix} ] \qquad Equation 24$$

The modal shape matrix Φ can be scaled with the identity

$${ϕ}_{k} ≡ \frac{{ϕ}_{k}}{\sqrt{{m}_{k}}}$$

to give the expression below in Equation 25.

$$Φ = [ \begin{matrix}\frac{{ϕ}_{1}}{\sqrt{{m}_{1}}} & … & \frac{{ϕ}_{N}}{\sqrt{{m}_{N}}}\end{matrix} ] \qquad Equation 25$$

The modal mass matrix can be normalized to Φ^{T}MΦ=I, where mₖ=1 is the modal mass for the k^{th} mode.

The modal stiffness matrix can be normalized to yield the expression below in Equation 26, where ωₖ² is the modal mass for the k^{th} mode.

$${Φ}^{T} K Φ = [ \begin{matrix}{k}_{1} & 0 & 0 \\ 0 & ⋱ & 0 \\ 0 & 0 & {k}_{N}\end{matrix} ] = [ \begin{matrix}{ω}_{1}^{2} & 0 & 0 \\ 0 & ⋱ & 0 \\ 0 & 0 & {ω}_{N}^{2}\end{matrix} ] \qquad Equation 26$$

This yields a mass normalized mode shape equation, which is a ratio of vⱼ, the displacement of the structural system at a first location j, to uᵢ, the force applied at a second location i, according to the expression in Equation 27 below.

$$\frac{{v}_{j} ( s )}{{u}_{i} ( s )} = {\sum }_{k = 1}^{n} \frac{{ϕ}_{k , j} {ϕ}_{k , i}}{{s}^{2} + 2 {ξ}_{k} {ω}_{k} s + {ω}_{k}^{2}} \qquad Equation 27$$

In Equation 27, ϕₖ is a vector representation of the mode shape of the structural system for the k^{th} mode given below in Equation 28, and ξₖ is a damping ratio.

$${ϕ}_{k} = ( \begin{matrix}{ϕ}_{k , 1} \\ ⋮ \\ {ϕ}_{k , N}\end{matrix} ) \qquad Equation 28$$

In certain embodiments, a plant model of the flexible mode dynamics of the structural system can be represented as a second order transfer function, such as given below in Equation 29.

$$M \ddot{v} + D \dot{v} + Kv = u \qquad Equation 29$$

The transfer function of Equation 29 can be transformed into modal coordinates using the relation v=Φq to yield the expression in Equation 30.

$${Φ}^{T} M Φ \ddot{q} + {Φ}^{T} D Φ \dot{q} + {Φ}^{T} K Φ q = {Φ}^{T} u \qquad Equation 30$$

The modal mass matrix term Φ^{T}MΦ can be as given above Equation 23, and the modal stiffness matrix Φ^{T}KΦ can be as given above in Equation 26. The damping matrix term Φ^{T}DΦ can be approximated as Equation 31 below.

$${Φ}^{T} D Φ \approx [ \begin{matrix}2 {ξ}_{1} {ω}_{1} & 0 & 0 \\ 0 & ⋱ & 0 \\ 0 & 0 & 2 {ξ}_{N} {ω}_{N}\end{matrix} ] \qquad Equation 31$$

The relation v=Φq can be written as given below in Equation 32, where N is the number of modes.

$$[ \begin{matrix}{v}_{1} \\ ⋮ \\ {v}_{N}\end{matrix} ] = [ \begin{matrix}{ϕ}_{1 , 1} & … & {ϕ}_{N , 1} \\ ⋮ & ⋱ & ⋮ \\ {ϕ}_{1 , N} & … & {ϕ}_{N , N}\end{matrix} ] [ \begin{matrix}{q}_{1} \\ ⋮ \\ {q}_{N}\end{matrix} ] \qquad Equation 32$$

A reduced order model of the system where n<N can be as given in Equation 33 below, where the term E_{j,i} is a DC approximation of neglected higher order dynamics given by Equation 34.

$$\frac{{v}_{j} ( s )}{{u}_{i} ( s )} = {E}_{j , i} + {\sum }_{k = 1}^{n} \frac{{ϕ}_{k , j} {ϕ}_{k , i}}{{s}^{2} + 2 {ξ}_{k} {ω}_{k} s + {ω}_{k}^{2}} \qquad Equation 33$$

$${E}_{j , i} = {\sum }_{k = n + 1}^{N \to ∞} \frac{{ϕ}_{k , j} {ϕ}_{k , i}}{{ω}_{k}^{2}} \qquad Equation 34$$

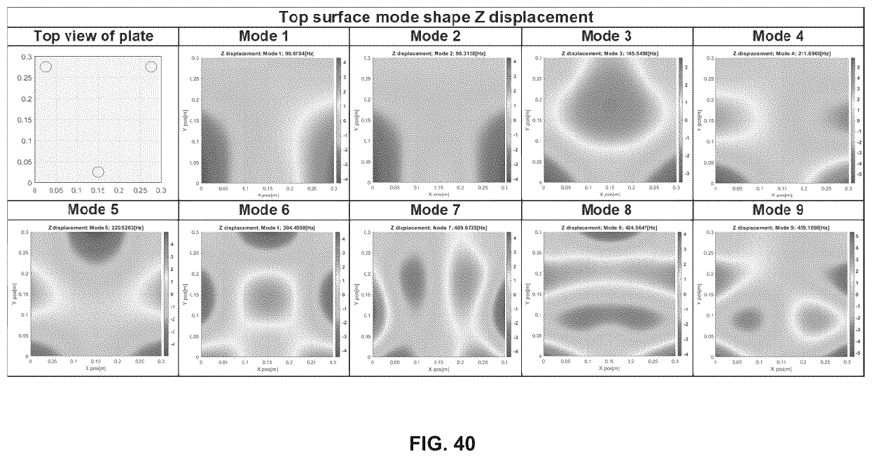

FIG. 40 illustrates simulations of the shape of the top surface of the plate member 1002 of FIG. 38 according to the FEA model described above when the plate member is supported at three locations. Displacement patterns associated with nine vibration modes of the plate member 1002 are shown in FIG. 40.

In certain embodiments, the accelerometer sensors can be placed at locations on the structural system where displacements from one or a plurality of vibration modes are greatest. For example, with reference to FIG. 40, the displacement of the top surface of the plate member 1002 in the z-direction (e.g., out of the plane of the page) is greatest at the lower left and lower right-hand corners in the first mode, as well as in the second mode. Thus, accelerometers located at those corners will provide clear signals of acceleration/displacement of the plate member surface associated with the first and second vibration modes. As can also be seen in FIG. 40, an accelerometer located at or near the center of the plate member 1002 can provide a clear signal of displacements associated with the third vibration mode. Thus, the accelerometers can be arranged at locations coinciding with large displacements of the plate surface for selected vibration mode(s) to be controlled. FEA models of the dynamics of a structural system can aid in determining placement of accelerometers and/or actuators, particularly in situations where the environment and/or constraints of a structural system in its intended application cannot be easily reproduced experimentally.

In certain embodiments, swapping the location of the actuator VCM with various accelerometers, in effect changing the input and output locations of the system, can result in similar vibration responses by the structural system. For example, placing the actuator VCM 1006 at the location of accelerometer 1010 in FIG. 38 and vice versa can yield a similar vibration profile in response to a disturbance force from the actuator VCM.

### Example 8: Estimation of Control Force Magnitude

In certain embodiments, models of the structural system dynamics such as described herein can be used, optionally in combination with measured vibration magnitude at the selected frequency to be damped, to estimate the magnitude of the force command sufficient to damp vibration at the selected mode frequency. In certain embodiments, rigid body modes (and/or flexible modes) of a structural element can be modeled using modal decomposition techniques. For example, in certain examples the displacement at a location j on a plate member similar to the plate member 1002 of FIG. 38 can be given by Equation 35 below.

$${v}_{j} = {P}_{j , i} ( s ) {u}_{i} + {\sum }_{l = 1}^{∞} {D}_{j , l} ( s ) {d}_{l} \qquad Equation 35$$

In Equation 35, the structural system plant dynamics P_{j,i}(s) can be determined according to Equation 33 above. The disturbance dynamics model D_{j,l}(s) can be given by Equation 36 below, but may require experimental verification in certain implementations.

$${D}_{j , l} ( s ) = \frac{{v}_{j} ( s )}{{d}_{l} ( s )} = {E}_{j , {d}_{l}} + {\sum }_{k = 1}^{n} \frac{{ϕ}_{k , j} {ϕ}_{k , {d}_{l}}}{{s}^{2} + 2 {ξ}_{k} {ω}_{k} s + {ω}_{k}^{2}} \qquad Equation 36$$

In certain embodiments, the magnitude of the displacements of the plate member at location j due to vibration at target mode k can be the absolute value of vⱼ, for example |vⱼ (jωₖ)|, when no control is applied (e.g., uᵢ=0). Thus, the magnitude of the force command to damp vibration at location j due to mode k vibration can be given by Equation 37 below.

$$\vert {u}_{i} ( j {ω}_{k} ) \vert = \frac{\vert {v}_{j} ( j {ω}_{k} ) \vert}{\vert {P}_{j , i} ( j {ω}_{k} ) \vert} \qquad Equation 37$$

In certain embodiments, the model of the structural system dynamics in the modal space can account for rigid body vibration modes of the structural system. FIG. 41 schematically illustrates an unconstrained structural element 1100 having length L, and indicating the x-coordinate xᵢ where force uᵢ is applied (e.g., by the actuator of the actuator system), along with the x-coordinate xⱼ of the displacement vⱼ of the member 1100 in response to the force uᵢ. In certain embodiments, for the first mode ϕ₁, where ω₁=0, ϕ_{1,i} and ϕ_{1,j} can equal

$$\frac{1}{\sqrt{m}}$$

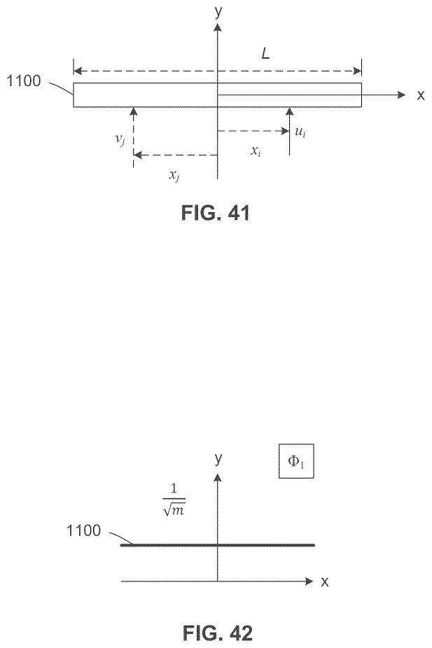

as given below in Equation 38. This relation is also illustrated in FIG. 42, which illustrates an exemplary first rigid body mode of the beam member of FIG. 41.

$${ϕ}_{1 , i} = {ϕ}_{1 , j} = \frac{1}{\sqrt{m}} \qquad Equation 38$$

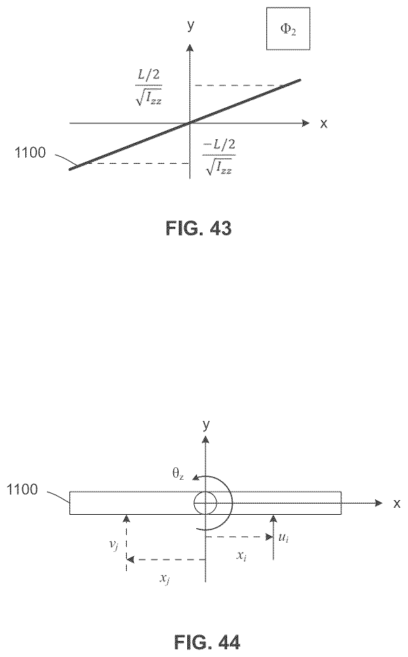

For a second rigid body mode ϕ₂ of the beam member illustrated in FIG. 43, where ω₂=0, ϕ_{2,i} can be expressed as given below in Equation 39 and ϕ_{2,j} can be expressed as given below in Equation 40, where I_{zz} is the moment of inertia of the structural element 1100 around the z-axis when the structural element is rotated around the z-axis.

$${ϕ}_{2 , i} = \frac{{x}_{i}}{\sqrt{{I}_{zz}}} \qquad Equation 39$$

$${ϕ}_{2 , j} = \frac{{x}_{j}}{\sqrt{{I}_{zz}}} \qquad Equation 40$$

By substituting the expressions in Equations 38-40 above, the ratio of

$$\frac{{v}_{j} ( s )}{{u}_{i} ( s )}$$

given in Equation 27 above can be rewritten and simplified according to Equation 41 below.

$$\frac{{v}_{j} ( s )}{{u}_{i} ( s )} = \frac{{ϕ}_{1 , j} {ϕ}_{1 , i}}{{s}^{2}} + \frac{{ϕ}_{2 , j} {ϕ}_{2 , i}}{{s}^{2}} = \frac{1}{m {s}^{2}} + \frac{{x}_{j} {x}_{i}}{{I}_{zz} {s}^{2}} \qquad Equation 41$$

When the two rigid-body modes ϕ₁ and ϕ₂ are considered, Equation 41 describes how the dynamics from input force uᵢ to contributes to the output position vⱼ for those two rigid body modes. A similar formulation can be extended to flexible modes of a structural element.

An example of the rotational mode about the z-axis is shown in FIG. 44, and can be expressed according to Equation 42 below.

$$\frac{{v}_{j} ( s )}{{u}_{i} ( s )} = \frac{{ϕ}_{2 , j} {ϕ}_{2 , i}}{{s}^{2}} \qquad Equation 42$$

Substituting the expressions for ϕ_{2,i} and ϕ_{2,j} in Equations 39 and 40 above can yield the series of equivalent expressions below in Equation 43 for the rotational mode θ_{z} about the z-axis illustrated in FIG. 44.

$$\frac{{v}_{j} ( s )}{{u}_{i} ( s )} = \frac{{x}_{j} {x}_{i}}{{I}_{zz} {s}^{2}} ⇔ \frac{{v}_{j} ( s ) / {x}_{j}}{{u}_{i} ( s ) {x}_{i}} = \frac{1}{{I}_{zz} {s}^{2}} ⇔ \frac{{θ}_{z} ( s )}{{T}_{z} ( s )} = \frac{1}{{I}_{zz} {s}^{2}} \qquad Equation 43$$

In certain embodiments, locating the actuator at a location on the structural system that results in a relatively large mode shape displacement in response to force application/input can result in improved controllability. A larger moment arm (e.g., the magnitude of the mode shape displacement at the point of force application or sensor measurement) for the actuator can result in a larger moment constant, which is the product of the actuator force constant and the moment arm at the actuator point. In certain embodiments, locating accelerometer sensors at locations with a relatively large mode shape displacement for a selected vibration mode can improve the ability of the accelerometer sensor to sense displacements of the structural element associated with the selected mode. Thus, in certain embodiments it can be beneficial to locate the actuator and/or sensor(s) at locations with relatively large mode shape displacement associated with the specified vibration mode to be damped.

In certain embodiments, the dynamic response of the structural system can also be formulated as a state space model. The ratio

$$\frac{{v}_{j} ( s )}{{u}_{i} ( s )}$$

can be expressed as given below in Equation 44, where vⱼ is the displacement at j, uᵢ is the force at i, and N is the number of vibration modes in the model.

$$\frac{{v}_{j} ( s )}{{u}_{i} ( s )} = {\sum }_{k = 1}^{N} \frac{{ϕ}_{k , j} {ϕ}_{k , i}}{{s}^{2} + 2 {ξ}_{k} {ω}_{k} s + {ω}_{k}^{2}} \qquad Equation 44$$

Equation 45 below provides an example of a single-input single output (SISO) system that is equivalent to the expression for

$$\frac{{v}_{j} ( s )}{{u}_{i} ( s )}$$

in Equation 44, where qₖ is the displacement of the structural element at the k^{th} mode.

$$\{ \begin{matrix}\begin{matrix}\frac{d}{dt} [ \begin{matrix}{\dot{q}}_{1} \\ ⋮ \\ {\dot{q}}_{N} \\ {q}_{1} \\ ⋮ \\ {q}_{N}\end{matrix} ] = \\ [ \begin{matrix}\begin{matrix}- 2 {ξ}_{1} {ω}_{1} & 0 & 0 \\ 0 & ⋱ & 0 \\ 0 & 0 & - 2 {ξ}_{N} {ω}_{N}\end{matrix} & \begin{matrix}- {ω}_{1}^{2} & 0 & 0 \\ 0 & ⋱ & 0 \\ 0 & 0 & - {ω}_{N}^{2}\end{matrix} \\ {I}_{N \times N} & {0}_{N \times N}\end{matrix} ] [ \begin{matrix}{\dot{q}}_{1} \\ ⋮ \\ {\dot{q}}_{N} \\ {q}_{1} \\ ⋮ \\ {q}_{N}\end{matrix} ] + [ \begin{matrix}{ϕ}_{1 , i} \\ ⋮ \\ {ϕ}_{N , i} \\ {0}_{N \times 1}\end{matrix} ] {u}_{i}\end{matrix} \\ {v}_{j} = [ \begin{matrix}{0}_{1 \times N} & {ϕ}_{1 , i} & … & {ϕ}_{N , j}\end{matrix} ] [ \begin{matrix}{\dot{q}}_{1} \\ ⋮ \\ {\dot{q}}_{N} \\ {q}_{1} \\ ⋮ \\ {q}_{N}\end{matrix} ] + [ {0}_{1 \times 1} ] {u}_{i}\end{matrix} \qquad Equation 45$$

In certain embodiments, the SISO system can include a term representative of residual elasticity associated with omitted higher order modes, which can be similar to Equation 34 above.

Equation 46 provides an exemplary multiple-input multiple-output (MIMO) system.

$$[ \begin{matrix}{v}_{1} \\ ⋮ \\ {v}_{M}\end{matrix} ] = [ \begin{matrix}\begin{matrix}{E}_{{v}_{1} , {u}_{1}} + \\ {\sum }_{k = 1}^{N} \frac{{ϕ}_{k , {v}_{1}} {ϕ}_{k , {u}_{1}}}{{s}^{2} + 2 {ξ}_{k} {ω}_{k} s + {ω}_{k}^{2}}\end{matrix} & … & \begin{matrix}{E}_{{v}_{1} , {u}_{L}} + \\ {\sum }_{k = 1}^{N} \frac{{ϕ}_{k , {v}_{1}} {ϕ}_{k , {u}_{L}}}{{s}^{2} + 2 {ξ}_{k} {ω}_{k} s + {ω}_{k}^{2}}\end{matrix} \\ ⋮ & ⋱ & ⋮ \\ \begin{matrix}{E}_{{v}_{M} , {u}_{1}} + \\ {\sum }_{k = 1}^{N} \frac{{ϕ}_{k , {v}_{M}} {ϕ}_{k , {u}_{1}}}{{s}^{2} + 2 {ξ}_{k} {ω}_{k} s + {ω}_{k}^{2}}\end{matrix} & … & \begin{matrix}{E}_{{v}_{M} , {u}_{L}} + \\ {\sum }_{k = 1}^{N} \frac{{ϕ}_{k , {v}_{M}} {ϕ}_{k , {u}_{L}}}{{s}^{2} + 2 {ξ}_{k} {ω}_{k} s + {ω}_{k}^{2}}\end{matrix}\end{matrix} ] [ \begin{matrix}{u}_{1} \\ ⋮ \\ {u}_{L}\end{matrix} ] \qquad Equation 46$$

Equation 46 can be expanded to the equivalent system of equations given in Equation 47.

$$\{ \begin{matrix}\begin{matrix}\frac{d}{dt} [ \begin{matrix}{\dot{q}}_{1} \\ ⋮ \\ {\dot{q}}_{N} \\ {q}_{1} \\ ⋮ \\ {q}_{N}\end{matrix} ] = [ \begin{matrix}\begin{matrix}- 2 {ξ}_{1} {ω}_{1} & 0 & 0 \\ 0 & ⋱ & 0 \\ 0 & 0 & - 2 {ξ}_{N} {ω}_{N}\end{matrix} & \begin{matrix}- {ω}_{1}^{2} & 0 & 0 \\ 0 & ⋱ & 0 \\ 0 & 0 & - {ω}_{N}^{2}\end{matrix} \\ {I}_{N \times N} & {0}_{N \times N}\end{matrix} ] \\ [ \begin{matrix}{\dot{q}}_{1} \\ ⋮ \\ {\dot{q}}_{N} \\ {q}_{1} \\ ⋮ \\ {q}_{N}\end{matrix} ] + [ \begin{matrix}\begin{matrix}{ϕ}_{1 , {u}_{1}} & … & {ϕ}_{1 , {u}_{L}} \\ ⋮ & ⋱ & ⋮ \\ {ϕ}_{N , {u}_{1}} & … & {ϕ}_{N , {u}_{1}}\end{matrix} \\ {0}_{N \times L}\end{matrix} ] [ \begin{matrix}{u}_{1} \\ ⋮ \\ {u}_{L}\end{matrix} ]\end{matrix} \\ \begin{matrix}[ \begin{matrix}{v}_{1} \\ ⋮ \\ {v}_{M}\end{matrix} ] = [ \begin{matrix}{0}_{M \times N} & \begin{matrix}{ϕ}_{1 , {v}_{1}} & … & {ϕ}_{N , {v}_{1}} \\ ⋮ & ⋱ & ⋮ \\ {ϕ}_{1 , {v}_{M}} & … & {ϕ}_{N , {v}_{M}}\end{matrix}\end{matrix} ] \\ [ \begin{matrix}{\dot{q}}_{1} \\ ⋮ \\ {\dot{q}}_{N} \\ {q}_{1} \\ ⋮ \\ {q}_{N}\end{matrix} ] + [ \begin{matrix}{E}_{{v}_{1} , {u}_{1}} & … & {E}_{{v}_{1} , {u}_{L}} \\ ⋮ & ⋱ & ⋮ \\ {E}_{{v}_{M} , {u}_{1}} & … & {E}_{{v}_{M} , {u}_{L}}\end{matrix} ] [ \begin{matrix}{u}_{1} \\ ⋮ \\ {u}_{L}\end{matrix} ]\end{matrix}\end{matrix} \qquad Equation 47$$

In certain embodiments, SISO and/or MIMO state space models of the structural system can be used to represent the system dynamics decoupled according to the modal coordinates, and can be more convenient in simulations than the transfer function models. In certain embodiments, the parameters ϕ_{k,j} and ϕ_{k,i} in Equations 44 and 46 can be used to determine the placement of actuators and sensors as described above since they relate to mode shape.

One or more of the actuator systems, control systems, and/or control methods described herein can provide significant advantages over known systems and methods of controlling structural vibrations in precision systems, such as lithography systems. For example, the actuator systems described herein can effectively attenuate vibrations of various structures in a lithography system. For example, the systems described herein can attenuate relatively low frequency vibrations (e.g., frequencies of 500 Hz or less, such 300 Hz or less, 200 Hz or less or 100 Hz or less), or higher frequency vibrations up to about 10 kHz (or the sampling and bandwidth limits of the system), reducing or eliminating the need for passive dampers for such a purpose. The disclosed systems and methods can also significantly reduce the peak magnitude of vibrations of a structural element associated with one or a plurality of vibration modes of the structural element. This can reduce relative motion of different structures in the precision system, such as the optical surface plate, the substrate stage, and/or the mask stage in a lithography exposure apparatus. Where one structural element serves as a position reference for another, this can significantly improve positioning accuracy by reducing the amplitude of the structural mode vibrations, which can be relatively large if not damped.

The systems and methods described herein can also significantly reduce the settling time of a structural system after excitation by a disturbance force. Such systems can be implemented, for example, to reduce vibrations in an exposure apparatus induced by motion of the substrate stage and/or the mask stage. As described above, certain configurations of the systems described herein can reduce the settling time of a structural system similar to an optical surface plate from one second or more to 0.2 seconds or less. This can significantly improve throughput in an exposure apparatus by reducing the time needed between exposures for vibrations to subside naturally, or under the influence of a passive damper.

The systems and methods described herein can also be adapted for use on a variety of structural elements, and in a variety of configurations. For example, in the context of an exposure apparatus, the actuator systems and control methods as described herein can be configured for use on the optical surface plate, the substrate stage, the mask stage, or any other structure of the exposure apparatus where damping of structural vibrations may be indicated. The control systems can be configured to attenuate one, two, three, four, five, or more vibration modes of a structural system, as well as vibrations excited by control of other modes. The control systems can also be configured to utilize feedback from sensors positioned at the location of the actuator(s) and/or remotely from the actuator(s) by implementing phase correction methods as described herein. The phase correction methods described herein can also be used to damp vibration modes of the structure having a lower frequency than the mode frequency of the actuator-structure interaction, as well as higher-frequency modes of the structure.

### Example 9: Exemplary Precision Systems

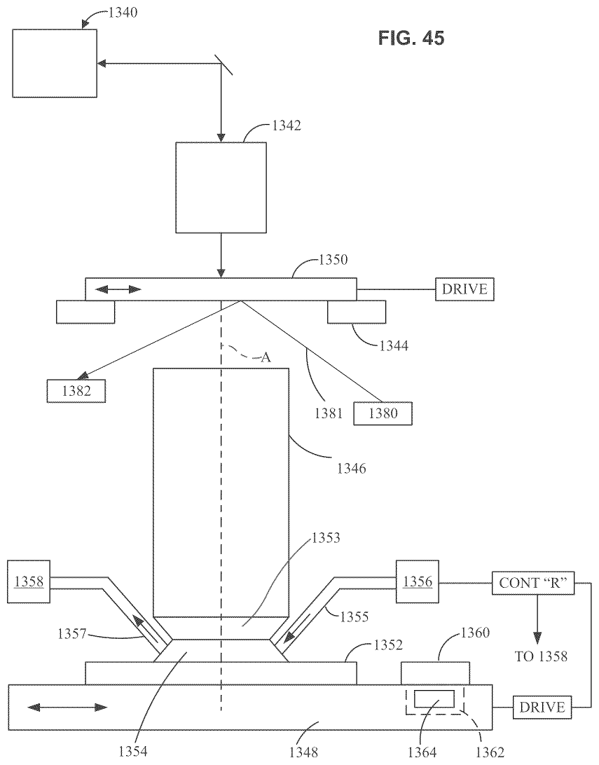

The methods and apparatus disclosed above can be used in conjunction with various precision systems such as various types of lithography systems and other wafer processing systems and methods, including the lithography exposure systems described above. The control systems and methods can also be used in combination with any of the precision system embodiments and methods described below with reference to FIGS. 45-49, and/or structural elements or subsystems associated therewith. Turning to FIG. 45, certain features of an immersion lithography system (an exemplary precision system) are shown, namely, a light source 1340, an illumination-optical system 1342, a reticle stage 1344, a projection-optical system 1346, and a wafer (substrate) stage 1348, all arranged along an optical axis A. The light source 1340 is configured to produce a pulsed beam of illumination light, such as DUV light of 248 nm as produced by a KrF excimer laser, DUV light of 193 nm as produced by an ArF excimer laser, or DUV light of 157 nm as produced by an F₂ excimer laser. The illumination-optical system 1342 includes an optical integrator and at least one lens that conditions and shapes the illumination beam for illumination of a specified region on a patterned reticle 1350 mounted to the reticle stage 1344. The pattern as defined on the reticle 1350 corresponds to the pattern to be transferred lithographically to a wafer 1352 that is held on the wafer stage 1348. Lithographic transfer in this system is by projection of an aerial image of the pattern from the reticle 1350 to the wafer 1352 using the projection-optical system 1346. The projection-optical system 1346 typically comprises many individual optical elements (not detailed) that project the image at a specified demagnification ratio (e.g., ¼ or ⅕) on the wafer 1352. So as to be imprintable, the wafer surface is coated with a layer of a suitable exposure-sensitive material termed a “resist.”

The reticle stage 1344 is configured to move the reticle 1350 in the X-direction, Y-direction, and rotationally about the Z-axis. To such end, the reticle stage is equipped with one or more linear motors having cooled coils as described herein. The two-dimensional position and orientation of the reticle 1350 on the reticle stage 1344 are detected by a laser interferometer (not shown) in real time, and positioning of the reticle 1350 is effected by a main control unit on the basis of the detection thus made.

The wafer 1352 is held by a wafer holder (“chuck,” not shown) on the wafer stage 1348. The wafer stage 1348 includes a mechanism (not shown) for controlling and adjusting, as required, the focusing position (along the Z-axis) and the tilting angle of the wafer 1352. The wafer stage 1348 also includes electromagnetic actuators (e.g., linear motors or a planar motor, or both) for moving the wafer in the X-Y plane substantially parallel to the image-formation surface of the projection-optical system 1346. These actuators desirably comprise linear motors, one more planar motors, or both.

The wafer stage 1348 also includes mechanisms for adjusting the tilting angle of the wafer 1352 by an auto-focusing and auto-leveling method. Thus, the wafer stage serves to align the wafer surface with the image surface of the projection-optical system. The two-dimensional position and orientation of the wafer are monitored in real time by another laser interferometer (not shown). Control data based on the results of this monitoring are transmitted from the main control unit to a drive circuits for driving the wafer stage. During exposure, the light passing through the projection-optical system is made to move in a sequential manner from one location to another on the wafer, according to the pattern on the reticle in a step-and-repeat or step-and-scan manner.

The projection-optical system 1346 normally comprises many lens elements that work cooperatively to form the exposure image on the resist-coated surface of the wafer 1352. For convenience, the most distal optical element (i.e., closest to the wafer surface) is an objective lens 1353. Since the depicted system is an immersion lithography system, it includes an immersion liquid 1354 situated between the objective lens 1353 and the surface of the wafer 1352. As discussed above, the immersion liquid 1354 is of a specified type. The immersion liquid is present at least while the pattern image of the reticle is being exposed onto the wafer.

The immersion liquid 1354 is provided from a liquid-supply unit 1356 that may comprise a tank, a pump, and a temperature regulator (not individually shown). The liquid 1354 is gently discharged by a nozzle mechanism 1355 into the gap between the objective lens 1353 and the wafer surface. A liquid-recovery system 1358 includes a recovery nozzle 1357 that removes liquid from the gap as the supply 1356 provides fresh liquid 1354. As a result, a substantially constant volume of continuously replaced immersion liquid 1354 is provided between the objective lens 1353 and the wafer surface. The temperature of the liquid is regulated to be approximately the same as the temperature inside the chamber in which the lithography system itself is disposed.

Also shown is a sensor window 1360 extending across a recess 1362, defined in the wafer stage 1348, in which a sensor 1364 is located. Thus, the window 1360 sequesters the sensor 1364 in the recess 1362. Movement of the wafer stage 1348 so as to place the window 1360 beneath the objective lens 1353, with continuous replacement of the immersion fluid 1354, allows a beam passing through the projection-optical system 1346 to transmit through the immersion fluid and the window 1360 to the sensor 1364.

An interrogation beam source 1380 is situated to direct an interrogation optical beam 1381 to the reticle 1350, and a detection system 1382 is configured to detect a portion of the interrogation beam as modulated by the reticle 1350. The detected beam can be used as described above to assess reticle distortion so that suitable system adjustments can be made to correct, prevent, or at least partially compensate distortion.

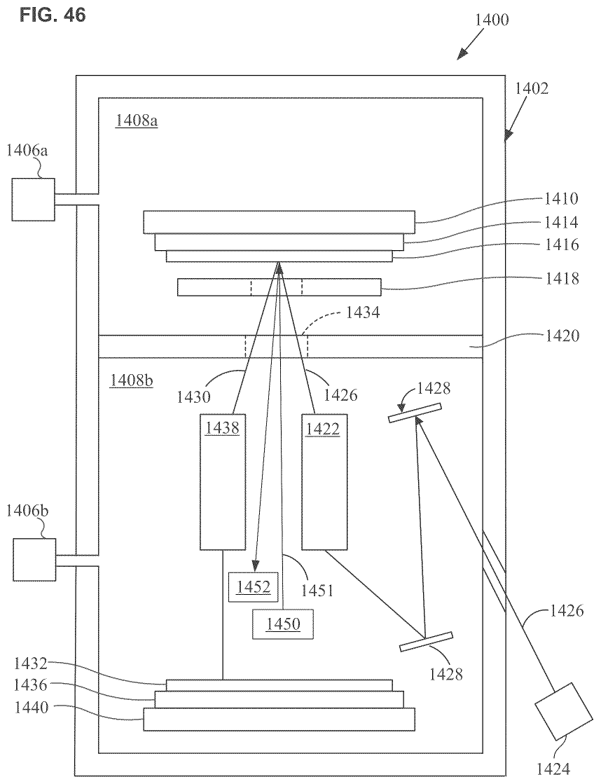

Referring now to FIG. 46, an alternative embodiment of a precision system that can include one or more electromagnetic actuators having actively cooled coils as described herein is an EUVL system 1400, as a representative precision system incorporating an electromagnetic actuator as described herein, is shown. The depicted system 1400 comprises a vacuum chamber 1402 including vacuum pumps 1406a, 1406b that are arranged to enable desired vacuum levels to be established and maintained within respective chambers 1408a, 1408b of the vacuum chamber 1402. For example, the vacuum pump 1406a maintains a vacuum level of approximately 50 mTorr in the upper chamber (reticle chamber) 1408a, and the vacuum pump 1406b maintains a vacuum level of less than approximately 1 mTorr in the lower chamber (optical chamber) 1408b. The two chambers 1408a, 1408b are separated from each other by a barrier wall 1420. Various components of the EUVL system 1400 are not shown, for case of discussion, although it will be appreciated that the EUVL system 1400 can include components such as a reaction frame, a vibration-isolation mechanism, various actuators, and various controllers.

An EUV reticle 1416 is held by a reticle chuck 1414 coupled to a reticle stage 1410. The reticle stage 1410 holds the reticle 1416 and allows the reticle to be moved laterally in a scanning manner, for example, during use of the reticle for making lithographic exposures. Between the reticle 1416 and the barrier wall 1420 is a blind apparatus. An illumination source 1424 produces an EUV illumination beam 1426 that enters the optical chamber 1408b and reflects from one or more mirrors 1428 and through an illumination-optical system 1422 to illuminate a desired location on the reticle 1416. As the illumination beam 1426 reflects from the reticle 1416, the beam is “patterned” by the pattern portion actually being illuminated on the reticle. The barrier wall 1420 serves as a differential-pressure barrier and can serve as a reticle shield that protects the reticle 1416 from particulate contamination during use. The barrier wall 1420 defines an aperture 1434 through which the illumination beam 1426 may illuminate the desired region of the reticle 1416. The incident illumination beam 1426 on the reticle 1416 becomes patterned by interaction with pattern-defining elements on the reticle, and the resulting patterned beam 1430 propagates generally downward through a projection-optical system 1438 onto the surface of a wafer 1432 held by a wafer chuck 1436 on a wafer stage 1440 that performs scanning motions of the wafer during exposure. Hence, images of the reticle pattern are projected onto the wafer 1432.

The wafer stage 1440 can include (not detailed) a positioning stage that may be driven by a planar motor or one or more linear motors, for example, and a wafer table that is magnetically coupled to the positioning stage using an EI-core actuator, for example. The wafer chuck 1436 is coupled to the wafer table, and may be levitated relative to the wafer table by one or more voice-coil motors, for example. If the positioning stage is driven by a planar motor, the planar motor typically utilizes respective electromagnetic forces generated by magnets and corresponding armature coils arranged in two dimensions. The positioning stage is configured to move in multiple degrees of freedom of motion, e.g., three to six degrees of freedom, to allow the wafer 1432 to be positioned at a desired position and orientation relative to the projection-optical system 1438 and the reticle 1416.

An EUVL system including the above-described EUV-source and illumination-optical system can be constructed by assembling various assemblies and subsystems in a manner ensuring that prescribed standards of mechanical accuracy, electrical accuracy, and optical accuracy are met and maintained. To establish these standards before, during, and after assembly, various subsystems (especially the illumination-optical system 1422 and projection-optical system 1438) are assessed and adjusted as required to achieve the specified accuracy standards. Similar assessments and adjustments are performed as required of the mechanical and electrical subsystems and assemblies. Assembly of the various subsystems and assemblies includes the creation of optical and mechanical interfaces, electrical interconnections, and plumbing interconnections as required between assemblies and subsystems. After assembling the EUVL system, further assessments, calibrations, and adjustments are made as required to ensure attainment of specified system accuracy and precision of operation. To maintain certain standards of cleanliness and avoidance of contamination, the EUVL system (as well as certain subsystems and assemblies of the system) are assembled in a clean room or the like in which particulate contamination, temperature, and humidity are controlled.

As shown in FIG. 46, an interrogation beam source 1450 can be situated so as to direct an interrogation optical beam 1451 to the reticle 1416. A detection system 1452 is situated to receive at least a portion of the interrogation beam that is reflected, refracted, diffracted, phase-shifted or otherwise modulated by interaction with the reticle 1416. Based on a detector signal response to this beam portion, reticle distortion can be assessed as described above in the detection system.

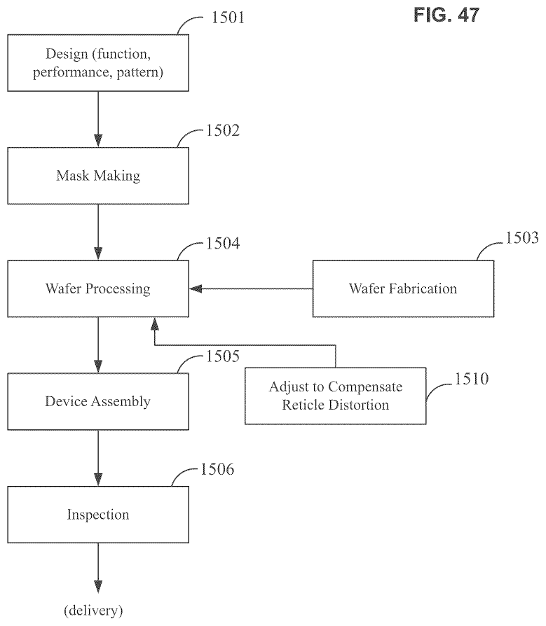

Semiconductor devices can be fabricated by processes including microlithography steps performed using a microlithography system as described above. Referring to FIG. 47, in step 1501 the function and performance characteristics of the semiconductor device are designed. In step 1502 a reticle (“mask”) defining the desired pattern is designed and fabricated according to the previous design step. Meanwhile, in step 1503, a substrate (wafer) is fabricated and coated with a suitable resist. In step 1504 (“wafer processing”) the reticle pattern designed in step 1502 is exposed onto the surface of the substrate using the microlithography system. In a step 1510, reticle distortion can be estimated during exposure as described above. In step 1505 the semiconductor device is assembled (including “dicing” by which individual devices or “chips” are cut from the wafer, “bonding” by which wires are bonded to particular locations on the chips, and “packaging” by which the devices are enclosed in appropriate packages for use). In step 1506 the assembled devices are tested and inspected.

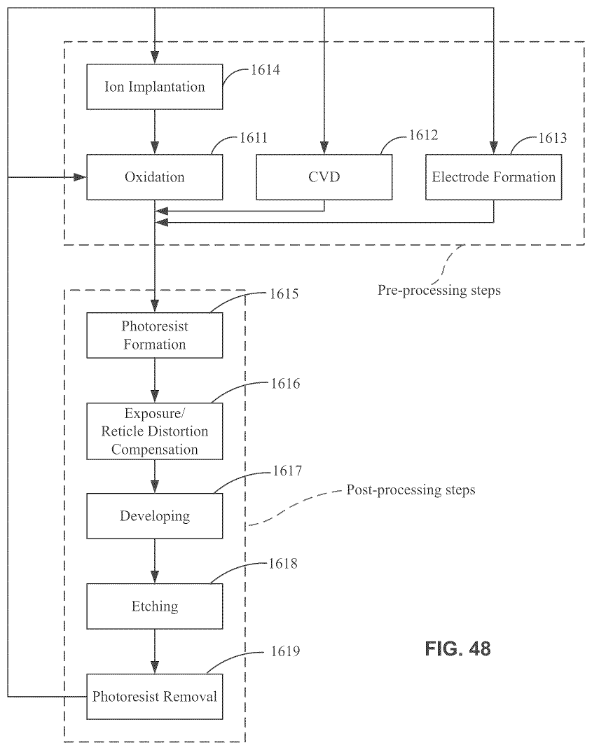

Representative details of a wafer-processing process including a microlithography step are shown in FIG. 48. In step 1611 (“oxidation”) the wafer surface is oxidized. In step 1612 (“CVD”) an insulative layer is formed on the wafer surface by chemical-vapor deposition. In step 1613 (electrode formation) electrodes are formed on the wafer surface by vapor deposition, for example. In step 1614 (“ion implantation”) ions are implanted in the wafer surface. These steps 1611-1614 constitute representative “pre-processing” steps for wafers, and selections are made at each step according to processing requirements.

At each stage of wafer processing, when the pre-processing steps have been completed, the following “post-processing” steps are implemented. A first post-process step is step 1615 (“photoresist formation”) in which a suitable resist is applied to the surface of the wafer. Next, in step 1616 (“exposure”), the microlithography system described above is used for lithographically transferring a pattern from the reticle to the resist layer on the wafer. Reticle distortion can be compensated during pattern transfer. In step 1617 (“developing”) the exposed resist on the wafer is developed to form a usable mask pattern, corresponding to the resist pattern, in the resist on the wafer. In step 1618 (“etching”), regions not covered by developed resist (i.e., exposed material surfaces) are etched away to a controlled depth. In step 1619 (“photoresist removal”), residual developed resist is removed (“stripped”) from the wafer.

Formation of multiple interconnected layers of circuit patterns on the wafer is achieved by repeating the pre-processing and post-processing steps as required. Generally, a set of pre-processing and post-processing steps are conducted to form each layer.

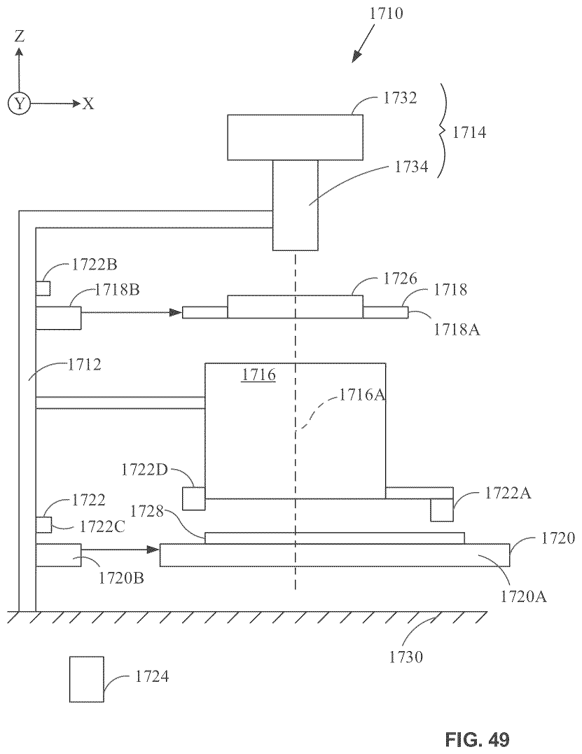

Included in this disclosure are any of various precision systems comprising a stage or the like that holds a workpiece or other item useful in a manufacture. An example of a precision system is a microlithography system or exposure “tool” used for manufacturing semiconductor devices. A schematic depiction of an exemplary microlithography system 1710, comprising features of the technology described herein, is provided in FIG. 49. The system 1710 includes a system frame 1712, an illumination system 1714, an imaging-optical system 1716, a reticle-stage assembly 1718A-1718B, a substrate-stage assembly 1720A-1720B, a positioning system 1722A-1722D, and a system-controller 1724. The configuration of the components of the system 1710 is particularly useful for transferring a pattern (not shown) of an integrated circuit from a reticle 1726 onto a semiconductor wafer 1728. The system 1710 mounts to a mounting base 1730, e.g., the ground, a base, or floor or other supporting structure. The system also includes a measurement system that measures the position of a lithographic substrate (as an exemplary workpiece) along an axis (e.g., the z-axis or optical axis) with improved accuracy and precision. In the system 1710, the reticle-stage assembly and/or the substrate-stage assembly 1720 include a multi-blade holding device as described in the above representative embodiments.

In certain examples, the specified vibration mode frequency can be 5 Hz to 10 KHz, 5 Hz to 5 kHz, 5 Hz to 1 kHz, 5 Hz to 500 Hz, 5 Hz to 300 Hz, 5 Hz to 200 Hz, 5 Hz to 100 Hz, 2 Hz to 10 kHz, 2 Hz to 5 kHz, 2 Hz to 1 kHz, 2 Hz to 500 Hz, 2 Hz to 300 Hz, 2 Hz to 200 Hz, 2 Hz to 100 Hz, 1 Hz to 10 kHz, 1 Hz to 5 kHz, 1 Hz to 1 kHz, 1 Hz to 500 Hz, 1 Hz to 300 Hz, 1 Hz to 200 Hz, 1 Hz to 100 Hz, or any range between any of the frequencies described herein. The specified vibration mode frequency can also be less than 1 Hz.

### Example 10: Representative Computing Environment

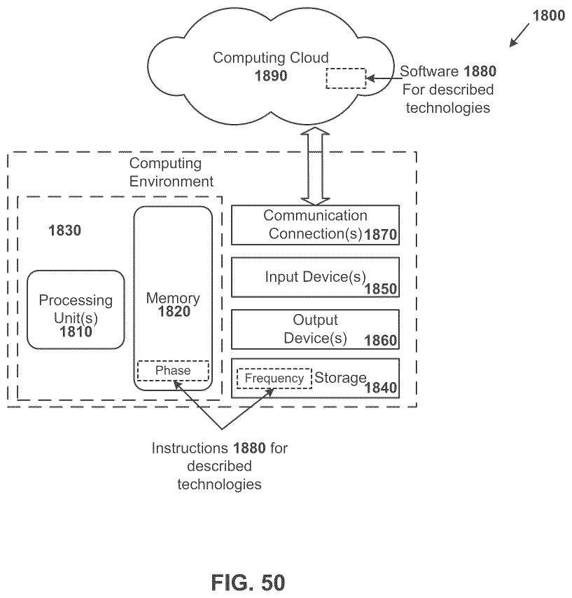

FIG. 50 illustrates a generalized example of a computing environment 1800 in which software and control algorithms for the described embodiments can be implemented. For example, software and/or hardware for implementing the various control systems, filters, and phase correction methods described herein can be configured similarly to the computing environment 1800, and can be a local computing system integrated as part of the exposure apparatus assembly or can be a remote computing system as described herein.

The computing environment 1800 is not intended to suggest any limitation as to scope of use or functionality of the technology, as the technology may be implemented in diverse general-purpose or special-purpose computing environments. For example, the disclosed technology may be implemented with other computer system configurations, including programmable automation controllers, programmable logic controllers, application-specific integrated circuits (ASICs), field-programmable gate arrays (FPGAs), hand held devices, multi-processor systems, programmable consumer electronics, network PCs, minicomputers, and the like. The disclosed control methodology may also be practiced in distributed computing environments where tasks are performed by remote processing devices that are linked through a communications network. In a distributed computing environment, program modules may be located in both local and remote memory storage devices.

With reference to FIG. 50, the computing environment 1800 includes at least one processing unit 1810 and memory 1820. In FIG. 50, this most basic configuration 1830 is included within a dashed line. The processing unit 1810 executes computer-executable instructions and may be a real or a virtual processor. In a multi-processing system, multiple processing units execute computer-executable instructions to increase processing power and as such, multiple processors can be running simultaneously. The memory 1820 may be volatile memory (e.g., registers, cache, RAM), non-volatile memory (e.g., ROM, EEPROM, flash memory, etc.), or some combination of the two. The memory 1820 stores software 1880 that can, for example, implement the technologies described herein. A computing environment may have additional features. For example, the computing environment 1800 includes storage 1840, one or more input devices 1850, one or more output devices 1860, and one or more communication connections 1870. An interconnection mechanism (not shown) such as a bus, a controller, or a network, interconnects the components of the computing environment 1800. Typically, operating system software (not shown) provides an operating environment for other software executing in the computing environment 1800, and coordinates activities of the components of the computing environment 1800.

The storage 1840 may be removable or non-removable, and includes non-volatile solid state memory, magnetic disks, or any other medium which can be used to store information and that can be accessed within the computing environment 1800. The storage 1840 stores instructions for the software 1880, plugin data, and messages, which can be used to implement technologies described herein.

The input device(s) 1850 may be, for example, an accelerometer, a position sensor such as an optical time-of-flight sensor, a temperature sensor, a position encoder, or a touch input device such as a keyboard, keypad, mouse, touch screen display, pen, or trackball, a voice input device, a scanning device, or another device, that provides input to the computing environment 1800. The output device(s) 1860 may be a wired or wireless signal transmitter, a display, or another device that provides output from the computing environment 1800.

The communication connection(s) 1870 enable communication over a communication medium (e.g., a connecting network) to devices or computing entities. The communication medium conveys information such as control signals, computer-executable instructions, sensor inputs or outputs, or other data in a modulated data signal. The communication connection(s) 1870 are not limited to wired connections (e.g., megabit or gigabit Ethernet, Infiniband, Fibre Channel over electrical or fiber optic connections) but also include wireless technologies (e.g., RF connections via Bluetooth, WiFi (IEEE 802.11a/b/n), WiMax, cellular, satellite, laser, infrared) and other suitable communication connections for providing a network connection for the disclosed controlled devices.

Some embodiments of the disclosed methods can be performed using computer-executable instructions implementing all or a portion of the disclosed technology in a computing cloud 1890 or other remote computing system. For example, the disclosed methods can be executed on processing units 1810 located in the computing environment 1830, or the disclosed methods can be executed on servers located in the computing cloud 1890.

Computer-readable media are any available media that can be accessed within a computing environment 1800. By way of example, and not limitation, with the computing environment 1800, computer-readable media include memory 1820 and/or storage 1840. As should be readily understood, the term computer-readable storage media includes the media for data storage such as memory 1820 and storage 1840, and not transmission media such as modulated data signals.

### Explanation of Terms

For purposes of this description, certain aspects, advantages, and novel features of the embodiments of this disclosure are described herein. The disclosed methods, apparatus, and systems are not limiting in any way. Instead, the present disclosure is directed toward all novel features and aspects of the various disclosed embodiments, alone and in various combinations and sub-combinations with one another. The methods, apparatus, and systems are not limited to any specific aspect or feature or combination thereof, nor do the disclosed embodiments require that any one or more specific advantages be present or problems be solved. The scope of this disclosure includes any features disclosed herein combined with any other features disclosed herein, unless physically impossible.

Although the operations of some of the disclosed embodiments are described in a particular, sequential order for convenient presentation, it should be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed components can be used in conjunction with other components.

As used in this disclosure and in the claims, the singular forms “a,” “an,” and “the” include the plural forms unless the context clearly dictates otherwise. Additionally, the term “includes” means “comprises.” Further, the terms “coupled” and “associated” generally mean electrically, electromagnetically, and/or physically (e.g., mechanically or chemically) coupled or linked and does not exclude the presence of intermediate elements between the coupled or associated items absent specific contrary language.

In some examples, values, procedures, or apparatus may be referred to as “lowest,” “best,” “minimum,” or the like. Such descriptions are intended to indicate that a selection among many alternatives can be made, and such selections need not be better, smaller, or otherwise preferable to other selections.

In the description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Unless otherwise indicated, all numbers expressing frequencies, material quantities, angles, pressures, molecular weights, percentages, temperatures, times, and so forth, as used in the specification or claims are to be understood as being modified by the term “about.” Accordingly, unless otherwise indicated, implicitly or explicitly, the numerical parameters set forth are approximations that can depend on the desired properties sought and/or limits of detection under test conditions/methods familiar to those of ordinary skill in the art. When directly and explicitly distinguishing embodiments from discussed prior art, the embodiment numbers are not approximates unless the word “about” is recited. Furthermore, not all alternatives recited herein are equivalents.

Although there are alternatives for various components, parameters, operating conditions, etc., set forth herein, that does not mean that those alternatives are necessarily equivalent and/or perform equally well. Nor does it mean that the alternatives are listed in a preferred order unless stated otherwise.

In view of the many possible embodiments to which the principles of the disclosed technology may be applied, it should be recognized that the illustrated embodiments are only examples and should not be taken as limiting the scope of the disclosure. Rather, the scope of the disclosure is at least as broad as the following claims and their equivalents. We therefore claim all that comes within the scope and spirit of these claims.

What is claimed is:

1. A method, comprising:
receiving data of a position of a structural element of an exposure apparatus;
determining a position error signal based at least in part on the position data and a specified position of the structural element;
applying phase correction to the position error signal;
determining a force command to damp a specified vibration mode frequency of the structural element based at least in part on the position error signal to which the phase correction has been applied and the specified vibration mode frequency; and
transmitting the force command to an actuator such that the actuator applies force to the structural element and damps vibration of the structural element at least at the specified vibration mode frequency of the structural element.

2. The method of claim 1, further comprising obtaining the position data by integrating an acceleration signal received from a sensor.

3. The method of claim 2, wherein determining the force command further comprises filtering the position error signal with a low-pass filter.

4. The method of claim 3, wherein the low-pass filter includes derivative control.

5. The method of claim 3, wherein the phase correction is applied with the low-pass filter.

6. The method of claim 1, wherein determining the force command further comprises filtering the position error signal with a bandpass filter.

7. The method of claim 1, wherein determining the force command further comprises filtering the position error signal with a notch filter.

8. The method of claim 1, wherein data of the position of the structural element is based on a signal received from a sensor coupled to the structural element at a location remote from the actuator.

9. The method of claim 1, wherein the specified vibration mode frequency is 2 Hz to 10 kHz, 2 Hz to 5 kHz, 2 Hz to 1 kHz, 2 Hz to 500 Hz, 2 Hz to 300 Hz, 2 Hz to 200 Hz, or 2 Hz to 100 Hz.

10. The method of claim 1, wherein the specified vibration mode frequency is lower than a vibration mode frequency of the actuator.

11. The method of claim 1, wherein determining the force command further comprises determining the force command to damp a plurality of specified vibration mode frequencies of the structural element.

12. The method of claim 11, wherein the structural element is an optical surface plate, a substrate stage, or a mask stage of the exposure apparatus.

13. A system, comprising:
an exposure apparatus including a structural element;
an actuator system coupled to the structural element, the actuator system comprising an actuator and a sensor; and
a control system configured to:
receive data of a position of the structural element from the sensor;
determine a position error signal based at least in part on the position data and a specified position of the structural element;
apply phase correction to the position error signal;
determine a force command to damp a specified vibration mode frequency of the structural element based at least in part on the position error signal to which the phase correction has been applied and the specified vibration mode frequency; and
transmit the force command to the actuator such that the actuator applies force to the structural element and damps vibration of the structural element at least at the specified vibration mode frequency of the structural element.

14. The system of claim 13, wherein the control system is further configured to obtain the position data by integrating an acceleration signal received from a sensor.

15. The system of claim 14, wherein the control system is further configured to filter the position error signal with a low-pass filter.

16. The system of claim 15, wherein the low-pass filter includes derivative control.

17. The system of claim 15, wherein the phase correction is applied by the low-pass filter.

18. The system of claim 13, wherein the control system is further configured to filter the position error signal with a bandpass filter.

19. The system of claim 13, wherein the control system is further configured to filter the position error signal with a notch filter.

20. The system of claim 13, wherein the sensor is spaced apart from the actuator on the structural element.

21. The system of claim 13, wherein the specified vibration mode frequency is 2 Hz to 10 kHz, 2 Hz to 5 kHz, 2 Hz to 1 kHz, 2 Hz to 500 Hz, 2 Hz to 300 Hz, 2 Hz to 200 Hz, or 2 Hz to 100 Hz.

22. The system of claim 13, wherein the structural element is an optical surface plate, a substrate stage, or a mask stage of the exposure apparatus.

23. A method, comprising:
receiving data of a position of a structural element of an exposure apparatus;
determining a position error signal based at least in part on the position data and a specified position of the structural element;
filtering the position error signal with a low-pass filter including derivative control;
applying phase correction to the position error signal with the low-pass filter;
determining a force command to damp a specified vibration mode frequency of the structural element based at least in part on the filtered, phase-corrected position error signal; and
transmitting the force command to an actuator coupled to the structural element such that the actuator applies force to the structural element and damps vibration of the structural element at least at the specified vibration mode frequency of the structural element.
